(19) United States
(12) Patent Application Publication
(10) Pub. No.: US 2025/0176424 A1
(43) Pub. Date: May 29, 2025

(54) METHOD OF FORMING METAL ION DOPED HALIDE PEROVSKITE MEGALIBRARIE

(71) Applicant: NORTHWESTERN UNIVERSITY, Evanston, IL (US)

(72) Inventors: Chad A. Mirkin, Wilmette, IL (US); Donghoon Shin, Evanston, IL (US); Tong Cai, Evanston, IL (US)

(21) Appl. No.: 18/963,353

(22) Filed: Nov. 27, 2024

Related U.S. Application Data
(60) Provisional application No. 63/602,863, filed on Nov. 27, 2023.

(51) Int. Cl. H10K 85/50; C07F 19/00; C09D 11/033; C09D 11/037; C09D 11/50; C09D 11/52; C09K 11/06; H10K 50/135; H10K 71/13; H10K 71/40

(52) U.S. Cl. CPC H10K 85/50; C07F 19/005; C09D 11/033; C09D 11/037; C09D 11/50; C09D 11/52; C09K 11/06; H10K 50/135; H10K 71/13; H10K 71/441; C09K 2211/10

(57) ABSTRACT

A method of forming metal ion doped halide perovskite nanocrystals includes forming metal halide perovskite nanocrystals, exposing the nanocrystals to a solvent vapor assisted recrystallization, and diffusing a metal ion dopant into the nanocrystals in a thermal annealing assisted cation exchange process.

### CROSS REFERENCE TO RELATED APPLICATION

The benefit of priority to U.S. Provisional Application No. 63/602,863 filed Nov. 27, 2023, is hereby claimed and the disclosure is incorporated herein by reference in its entirety.

### STATEMENT OF GOVERNMENT SUPPORT

This invention was made with government support under grant numbers FA9550-22-1-0300 and FA9550-17-1-0348 awarded by the Air Force Office of Scientific Research.

The government has certain rights in the invention.

### FIELD

The disclosure relates to a method for synthesis of metal ion-doped perovskites and megalibriaries containing the same for high throughput screening of light emitting materials.

### BACKGROUND

White light-emitting diodes (WLEDs) are widely used and are important to human society owing to their high brightness and efficiency, and capability to provide a high color-rendering index and adjustable correlated color temperature. However, traditional methods of generating white light emission using multiple color conversion layers suffer from issues such as long-term instability, complex device fabrication, and high costs. To address these challenges, single-component white light emitters have been developed by introducing different emission channels within a single material to achieve polychromatic light in a cost-effective manner.

Metal halide perovskites have shown great potential as light-emitting materials due to their unique optoelectronic properties, such as high photoluminescence (PL) quantum yield, tunable bandgaps, and narrow emission peaks. Doping impurity ions (e.g., Mn²⁺) into perovskites is one effective strategy to achieve dual-wavelength PL through energy transfer, which holds promise for generating white light emission. However, discovering new single-component white light emitting doped perovskite materials using traditional material synthesis and characterization methods is time-consuming.

### SUMMARY

There is a need to accelerate the material discovery of novel light-emitting materials in order to advance carbon neutrality, conserve energy, and improve the cost-effectiveness and quality of illumination.

Methods of the disclosure refer to high throughput synthesis and evaluation of materials systems that can deepen the understanding of composition-PL-chromaticity relationships and consequently expedite the inverse design of customized single-composition light emitters, regardless of desired color. These methods further lay the foundation for a general approach to mapping the vast compositional space of halide perovskites, independent of the choice of cations or anions employed.

A method of forming a metal ion doped mixed-ion perovskite nanocrystal array having a plurality of metal ion doped halide perovskite nanocrystals arranged in a pattern, each halide perovskite being of the formula ABX₃, wherein A comprises one or more cations, B comprises one or more metal cations, X comprises one or more halogens, in accordance with the disclosure can include contacting a substrate with a coated pen array coated with a first ink to thereby deposit the first ink as a pattern of printed indicia on the substrate. The printed indicia form nanoreactors on the substrate and a halide perovskite nanocrystal nucleates and grows within each nanoreactor to form the halide perovskite nanocrystal array. The method further includes exposing the halide perovskite nanocrystals to a crystallization solvent vapor for recrystallization of the halide perovskite; and thermally annealing the halide perovskite nanocrystals to promote a cation exchange process whereby B′ diffuses into the halide perovskite nanocrystals and exchanges with a portion of B to thereby form the doped perovskite nanocrystals. The first ink comprises at least one first perovskite precursor having the formula AX¹, at least one second perovskite precursor having the formula BX²₂, and at least one third perovskite precursor having the formula B′X¹₂ and/or B′X²₂ dissolved in a solvent, wherein B′ comprises one or more dopant metal cation, and X¹ and X² are each a halogen. B′ and B are different metal cations or metal cations of the same metal having different valency, and X¹ and X² are the same halogen when X comprises one halogen and X¹ and X² are different halogens when X comprises more than one halogen.

According to the disclosure a metal ion doped perovskite having a formula PEA₂Pb_{0.75}Mn_{0.25}(Br_{0.3}I_{0.7})₄ can emit white light with a CIE chromaticity coordinate of about (0.33, 0.33).

A method of forming a metal ion doped perovskite nanocrystal array having a plurality of metal ion doped halide perovskite nanocrystals arranged in a pattern, each halide perovskite being of the formula A′₂Aₙ₋₁BₙX₂ₙ₊₁, wherein n is at least 1, A′ comprises one or more organic compounds, A, when present, comprises one or more cations, and X comprises one or more halogens, in accordance with the disclosure can include contacting a substrate with a coated pen array coated with a first ink to thereby deposit the first ink as a pattern of printed indicia on the substrate. The printed indicia form nanoreactors on the substrate and a halide perovskite nanocrystal nucleates and grows within each nanoreactor to form the halide perovskite nanocrystal array. The method further includes exposing the halide perovskite nanocrystals to a crystallization solvent vapor for recrystallization of the halide perovskite; and thermally annealing the halide perovskite nanocrystals to promote a cation exchange process whereby B′ diffuses into the halide perovskite nanocrystals and exchanges with a portion of B to thereby form the doped perovskite nanocrystals. The first ink comprises at least one first perovskite precursor having the formula A′X¹, at least one second first perovskite precursor having the formula AX¹ when n is greater than 1, at least one second perovskite precursor having the formula BX²₂, and at least one third perovskite precursor having the formula B′X¹₂ and/or B′X²₂ dissolved in a solvent. B′ and B are different metal cations or metal cations of the same metal having different valency, and X¹ and X² are the same halogen when X comprises one halogen and X¹ and X² are different halogens when X comprises more than one halogen.

### BRIEF DESCRIPTION OF THE DRAWINGS

FIG. 1 shows a series of schematics of the Evaporation Crystallization-Polymer Pen Lithography (EC-PPL) process, Solvent Vapor-Assisted Recrystallization (SVAR) and thermal annealing processes, and exemplary structures of Mn⁺² doped perovskites.

FIGS. 2A-2D are microscopy images of Mn²⁺ doped PEA₂PbBr₄ perovskite megalibraries. (A) Optical dark field. (B) scanning electron microscopy (SEM). (C) Energy-dispersive x-ray spectroscopy (EDS) elemental mapping. (D) Atomic force microscopy (AFM) height images.

FIG. 2E is a Transmission Electron Microscopy (TEM) image and selected-area electron diffraction (SAED) (inset, scale bar: 10 nm⁻¹) of a Mn²⁺-doped PEA₂PbBr₄ perovskite NC.

FIG. 2F-2G are Multiphoton Confocal Laser Scanning Microscope (MP CLSM) images of a perovskite NC array corresponding to (F) the blue channel: from 380 nm to 500 nm and (G) the orange channel: from 500 nm to 700 nm.

FIG. 2H is a spectrum of the photoluminescence signal of a Mn²⁺ doped PEA₂PbBr₄ perovskite NC in an array.

FIG. 3A is a schematic of PL measurements of a single Mn²⁺ doped PEA₂PbBr₄ perovskite NC in an array (Left), crystal structure of 2D Mn²⁺ doped PEA₂PbBr₄ perovskites (Middle), and a schematic of proposed energy transfer mechanisms from the PEA₂PbBr₄ perovskite host to the Mn²⁺ dopants (Right).

FIGS. 3B to 3D show a series of spectra of the PL emission of perovskite and Mn PL as a function of (B) Laser power, (C) repetition rate, and (D) temperature.

FIGS. 3E-3G are a series of plots of the intensities of the emission peaks of the perovskite PL and Mn PL as function of (E) Laser power, (F) repetition rate, and (G) temperature.

FIGS. 4A-4D are a series of crystal structure atomic models, optical dark-field images, SEM images, EDS elemental mappings, and PL spectra of (A) Mn²⁺-doped BA₂PbBr₄ perovskite NCs, (B) Mn²⁺-doped PEA₂PbI₄ perovskite NCs, (C) Mn²⁺-doped CsPbCl₃ perovskite NCs and (D) Mn²⁺-doped CsPbBr₃ perovskite NCs.

FIG. 5A is a schematic of the spray-coating assisted combinatorial inking process and the high-throughput synthesis of NC megalibraries.

FIG. 5B is a heatmap of the fitted two-ink spray profile of a 1.5×1.5 cm² pen array.

FIG. 5C-5E are a series of microscopy images of perovskite NC megalibraries. (C) Low magnification optical image, (D) medium magnification optical image, (E) high magnification dark-field optical image.

FIG. 5F is a series of selected confocal microscopy PL images for PEA₂Pb(Br₁₋ₓIₓ)₄ perovskite megalibraries.

FIG. 5G is a series of single-particle PL spectra of 100 perovskite individual NCs in the selected NC array.

FIG. 5H is a spectrum of the average PL of all NCs in the selected NC array from 5G.

FIG. 5I is a CIE chromaticity diagram of the chromaticity coordinates of the 100 individual perovskite NCs in 5G.

FIG. 6A is an atomic model of PEA₂Pb_{1-y}Mn_{y}(Br₁₋ₓIₓ)₄ perovskites.

FIGS. 6B-6F are series of the evolution of PL spectra of (B) PEA₂Pb(Br₁₋ₓIₓ)₄, (C) PEA₂Pb_{1-y}Mn_{y}Br₄, (D) PEA₂Pb_{0.20}Mn_{0.30}(Br₁₋ₓIₓ)₄, (E) PEA₂Pb_{1-y}Mn_{y}(Br_{0.30}I_{0.70})₄, and (F) PEA₂Pb_{0.75}Mn_{0.25}(BrₓI₁₋ₓ)₄ perovskites as a function of halide composition ratio or Mn²⁺ doping concentration (0≤x≤1, 0≤y≤1).

FIG. 6G is a CIE chromaticity diagram showing the composition tuning triangle and on-demand screening for white light emitters.

FIG. 6H is the PL spectrum of PEA₂Pb_{0.75}Mn_{0.25}(Br_{0.30}I_{0.70})₄ white light emitter.

FIGS. 7A-7C is a series of SEM images of a Mn²⁺-doped PEA₂PbBr₄ perovskite NP under (A) no treatment, (B) direct heating at 100° C. for 10 minutes, (C) solvent vapor annealing at 40° C. for 10 minutes.

FIG. 8 is a series of PL spectra of Mn²⁺-doped PEA₂PbBr₄ perovskite NPs annealed at different temperatures.

FIG. 9 is an AFM image (left) and a height profile (right) of a Mn²⁺-doped PEA₂PbBr₄ perovskite NC.

FIG. 10 is a FLIM image of Mn²⁺-doped PEA₂PbBr₄ perovskite NPs.

FIG. 11 is a set of spectra of the lifetime decay of undoped and Mn²⁺-doped PEA₂PbBr₄ perovskite NPs.

FIG. 12 is a schematic of the set-up for single-particle optical PL measurements.

FIG. 13 is a plot of the percentage of photons emitted via Mn PL as a function of the total collected emitting photons based on laser power density.

FIG. 14 is a plot of the percentage of emitted photons based on Mn PL emission as compared to the total collected emitting photons as a function of laser repetition rate.

FIGS. 15A-15B are schematics of the proposed energy transfer processes for (A) Mn²⁺ doped perovskites with wide bandgaps (i.e., PEA₂PbBr₄, BA₂PbBr₄ and CsPbCl₃) and (B) Mn²⁺ doped perovskites with narrow bandgaps (i.e., PEA₂PbI₄ and CsPbBr₃).

FIG. 16A shows the evolution of PL spectra of MAPbCl₁₋ₓBrₓ perovskites with varying halide composition ratio (x, ratio=Br/[Br+Cl]).

FIG. 16B is a plot of the PL peak energy as a function of halide composition ratio.

FIG. 16C is a heatmap of the experimental spray profile for the gradient composition distribution using two inks spraying on the corners. The composition ratio is calculated as Ink 1/[Ink 1+Ink 2].

FIG. 17 is a contour plot of the spray profile generated from a Gaussian fitting with the spray centered over the top left corner.

### DETAILED DESCRIPTION

Metal halide perovskite nanocrystals (NCs) have exhibited enormous potential as next-generation light-emitting materials due to their high photoluminescence (PL) quantum yield, tunable bandgaps, and narrow emission peaks.

Methods of the disclosure can speed up the exploration of new perovskite semiconductor materials by high-throughput synthesis and screening of metal ion doped perovskite megalibraries, leading to the rapid development of novel materials with improved functionalities for various optoelectronic applications, such as light-emitting diodes, solar cells, photodetectors, and photocatalysis. The ability to rapidly screen a large number of compositions vs. traditional single-composition synthesis, and identify optimized materials allows for efficient material design and large-scale synthesis. In methods of the disclosure, evaporation crystallization-polymer pen lithography (EC-PPL) can be integrated with spray inking to allow for finely tuned composition gradients and the synthesis of perovskite NC megalibraries of diverse compositions and structures. In addition, optical screening according to the disclosure can allow for the construction of chromaticity palettes that serve not only to identify white light emitters, but also to pave the way for the exploration of novel optical emitters with customized colors through inverse material design. Indeed, the chromaticity palette concept can be extended to other materials with tailorable band gaps or light emitting properties This not only facilitates the advancement of scientific knowledge but also paves the way for practical applications in clean energy, sustainability, and quantum technologies.

Doped halide perovskites formed in accordance with the methods of the disclosure can have the general formula ABX₃, (formula I) with a dopant metal cation B′ exchanged with some of the B sites of the crystal. A is one or more cations, B is one or more metal cations, X is one or more halogens, and B′ is one or more dopant metal cations. B and B′ can be ions of different metals or can be ions of the same metal but having different valency.

Doped halide perovskites formed in accordance with the methods of the disclosure can alternatively be a layered structure and have the general formula A′₂Aₙ₋₁BₙX₂ₙ₊₁ (Formula II), with a dopant metal cation B′ cation exchanged with some of the B sites, where n indicates the number of BX₆ octahedra stacked in each slab, A′ is one or more organic cations, A is one or more cations, organic or inorganic, B is one or more metal ions, X is one or more halogens, and B′ is a one or more dopant metal cations. B and B′ can be ions of different metals or can be ions of the same metal but having different valency. In the layered structure, when n=1, there is no A cation and the 2D slab is one octahedron thick with a general formula A′BX₄ (Formula III). In formula II, n is at least 1 and can be any suitable number depending on the octahedra desired to be stacked in each slab.

Methods of synthesizing metal ion doped halide perovskite arrays in accordance with the disclosure can include printing a pattern of nanoreactors from an ink using an array of pens. For example, polymer pen lithography can be used. As is known in the art, polymer pen lithography uses an array of pyramidal pens, each pen being joined to a common surface and having a tip oppositely disposed the common surface. The tip is the portion of the pen that contacts the substrate. Various other known tip-based patterning tools can be used as known in the art, including, but not limited to, dip-pen nanolithography, hard-tip, soft-spring lithography, and microcontact printing. As is generally known in the art, the pens of the array have a tip, which can have a radius of curvature of less than 1 μm. The pens generally have a height on the microscale. The pens can have various shapes. For example, the pens can be pyriamidal. For example, the pens can have a pyriamidal shape, following KOH etching of a Si wafer.

The ink contains the halide perovskite precursors dissolved in a solvent or solvent system. Reference herein to a solvent should be understood to include a single solvent as well as a solvent system having a combination of solvents.

In forming doped halide perovskites having the general formula of Formula I (ABX₃), the ink includes at least one first perovskite precursor having the formula AX¹, at least one second perovskite precursor having the formula BX², and at least one third perovskite precursor having the formula B′X¹ and/or B′X². In these formula A is one or more cations, B is one or more metal cations, B′ is one or more dopant metal cations, X¹ and X² are same halogen when X in the perovskite of formula I is a single halogen (and are the sample halogen as X in formula I) and are different halogens when X the perovskite of formula I is more than one halogen, representing each halogen present in perovskite to be formed. For example, any number of additional second perovskite precursors having the formula, for example, BX^{2+z} can be included for each additional halogen to be included, where z is in integer to represents the additional number of halogens to be included. In embodiments in which the halide perovskite has more than one A cation, the ink includes a first perovskite precursor for each cation. Similarly, where the halide perovskite to be formed has more than one B cation, the ink can include more than one second perovskite precursor for each cation. Still further, where the halide perovskite to be formed has more than one B′ dopant metal cation, the ink can include more than one third perovskite precursor for each cation. Any suitable number of precursors can be included in the ink depending on the number of different types of A′, A, B, B′ cations to be included in the perovskite to be formed, as well as the number of halogens.

In forming the doped halide perovskite having the general formula of Formula II (A′₂Aₙ₋₁BₙX₂ₙ₊₁), the ink includes at least one first, first perovskite precursor having the formula A′X¹, at least one second first perovskite precursor having the formula AX (except when n=1 in Formula II), at least one second perovskite precursor having the formula BX², and at least one third perovskite precursor having the formula B′X¹ and/or B′X². In these formula A′ is one or more organic cations, A is one or more cations, B is one or more metal cations, B′ is one or more dopant metal cations, X¹ and X² are same halogen when X in the perovskite of formula I is a single halogen (and are the sample halogen as X in formula I) and are different halogens when X the perovskite of formula I is more than one halogen, representing each halogen present in perovskite to be formed. For example, additional second perovskite precursors having the formula BX³ can be included where a further halogen is to be included. For example, any number of additional second perovskite precursors having the formula, for example, BX^{2+z} can be included for each additional halogen to be included, where z is in integer to represents the additional number of halogens to be included. In embodiments in which the halide perovskite has more than one A′ cation, the ink includes a first, first perovskite precursor for each cation. When the halide perovskite has one or more A cations, the ink includes a second first perovskite precursors for each cation. Similarly, where the halide perovskite to be formed has more than one B cation, the ink can include more than one second perovskite precursor for each cation. Still further, where the halide perovskite to be formed has more than one B′ dopant metal cation, the ink can include more than one third perovskite precursor for each cation. Any suitable number of precursors can be included in the ink depending on the number of different types of A′, A, B, B′ cations to be included in perovskite to be formed, as well as the number of halogens. In forming compounds of Formula III, where n=1 and A is not present, the ink does not include at least one second, first perovskite precursor.

In one aspect of the disclosure at least one perovskite and the at least one second perovskite precursor are present in the first ink in substantially equimolar amounts.

In one aspect of the disclosure a molar ratio of the at least one first perovskite precursor to the at least one second perovskite precursor in the first ink is about 2:1 for the layered perovskites with a general formula (II).

The ratio of the precursors in the ink is selected to satisfy the stoichiometry of the targeted perovskite. For example, when X¹ and X² are the same halogen, the ratio of the precursors is typically about 1:1. This ratio is adjusted for mixed-ion perovskites (formula I) as well as layered perovskites (formula II) to satisfy the target stoichiometry. For example, for the mixed-ion perovskite MAPb(Br_{0.4}Cl_{0.6})₃, the ratio is MABr:MACl:PbBr₂:PbCl₂=2:3:2:3.

The ink can be coated onto a pen array using various known methods, including, but not limited to, spin coating, dip coating, and spray coating. Spray coating can be used, for example, to form a gradient of ink compositions on the tips. For example, a first ink can be sprayed across the pen array in a first gradient in a first direction and a second ink can be sprayed across the pen array in a second gradient in a second direction, such that the pen array is coated in a gradient composition of first and second inks to form mixed perovskite structures. The first ink and the second ink can be different in one or more of composition, precursor amounts, relative concentrations of precursors, solvent system, and the like. The ink can have a high surface tension and low viscosity that allows the ink to accumulate around the base and serve as a reservoir for continuous inking.

The ink can be deposited in a defined pattern, resulting in nanoreactors being formed on the substrate in the defined pattern and ultimately nanocrystals arranged in the defined pattern.

Further, as is known with lithographic techniques such as polymer pen lithography, control of the extension length and/or contact time can be used to control the size of the deposited feature. It has been found that the size of the deposited feature directly correlates to the ultimate size of the nanocrystal formed from the deposited nanoreactor. The larger the deposited feature, the larger the nanocrystal formed. Such control over the deposition can be used to generate gradients of sizes, resulting in an array of halide perovskite nanocrystal having a gradient of crystal sizes. Such control over size can be used to produce combinatorial libraries of halide perovskite nanocrystals with controlled and defined size variations within the library. Changes in extension length and/or contact time can be further or alternatively used to vary the pattern or feature size of a single patterning step or in a multiple-step patterning process.

The methods of the disclosure can be used to form combinatorial libraries of metal ion doped halide perovskite nanocrystals. Combinatorial libraries of the disclosure can include an array of nanocrystals.

In embodiments, the combinatorial library includes halide perovskite nanocrystals having the same composition. In embodiments, the combinatorial library has two or more different compositions of halide perovskite nanocrystals. For example, the combinatorial library can include doped halide perovskite nanocrystals and undoped halide perovskite nanocrystals. For example, the combinatorial library can include doped halide perovskite nanocrystals with different dopants.

In embodiments, the combinatorial library includes halide perovskite nanocrystals having the same geometry. In embodiments, the combinatorial library has two or more halide perovskite nanocrystal geometries.

In any of the foregoing embodiments, combinations of features such as size difference, compositional differences, geometry differences or patterning can be combined in the combinatorial library.

In any of the foregoing embodiments, the nanocrystals can have a size of about 20 nm to about 1000 nm, about 20 nm to about 50 nm, or about 50 nm to about 100 nm. Other sizes of nanocrystals include about 20, 25, 30, 35, 40, 45, 50, 55, 60, 65, 70, 75, 80, 85, 90, 95, 100, 150, 200, 250, 300, 350, 400, 450, 500, 550, 600, 650, 700, 750, 800, 850, 900, 950, 1000 nm. Larger crystal sizes than 1000 nm can be formed with the methods of the disclosure. However, the methods of the disclosure are particularly useful in forming small crystal sizes, which cannot be readily achieved with prior halide perovskite formation methods.

In any of the foregoing embodiments, the nanocrystals can have a geometry selected from plates, particles, rods, and core-shell structures. Without intending to be bound by theory, it is believed that the geometry of the nanocrystals can be adjusted through control of the solubility of the precursors in the ink, for example, by selection of the solvent or solvent system. For example, in embodiments, by selecting for the inks different solvents having different solubility of the precursors therein, the methods of the disclosure can be used to form a first perovskite nanocrystal, with a second perovskite nanocrystal being formed around the first perovskite nanocrystal like a heterostructure.

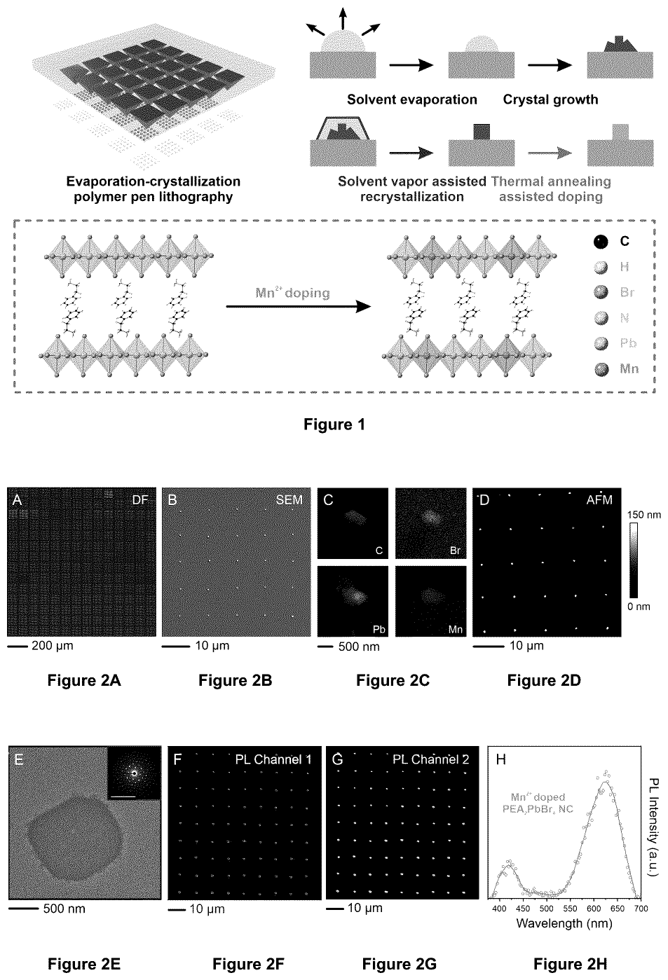

Referring to FIG. 1A, once the tips are inked and the polymer pen array is brought into contact with the surface and retracted, thereby depositing the ink onto the substrate forming a nanoreactor, the solvent evaporates quickly due to the high surface-to-volume ratio, which leads to the nucleation and growth of individual halide perovskite nanocrystals. All or substantially all of the nanoreactors result in formation of single crystal halide perovskite nanocrystals. The method of the disclosure further includes solvent vapor-assisted recrystallization (SVAR) and metal ion doping with thermal annealing treatment. In the solvent vapor assisted recrystallization, the substrate with nanoparticle arrays can be placed in a chamber with controlled environment where a desired crystallization solvent vapor is introduced in advance. For example, a liquid solvent can be placed into the chamber and heated to a crystallization temperature to generate a vaporized atmosphere of the solvent. The nanoparticle array can then be placed in the chamber for exposure to the crystallization solvent vapor for a crystallization time. The crystallization time can be at least 10 minutes or about 10 minutes to about 25 minutes. For example, the crystallization time can be about 10 minutes to about 15 minutes, about 12 minutes to about 20 minutes, about 15 minutes to about 25 minutes, or about 10, 12, 15, 18, 20, 22, 25 minutes or any value therebetween or ranges defined by such values.

The crystallization solvent in the SVAR step can have a flash point of 70° C. or less, 60° C. or less, or 50° C. or less. For example, the flash point can be about 40° C. to about 70° C., about 60° C. to about 70° C., or 40, 45, 50, 52, 55, 58, 60, 62, 66, 68, 70° C. or any values therebetween or ranges defined by such values. The crystallization solvent can be one or more of dimethylformamide (DMF), dimethylsulfoxide (DMSO), acetonitrile, 2-methoxyehanol, methanol. Without intending to be bound by theory, it is believed that a solvent with low flash point can facilitate recrystallization of small crystals into a larger single crystal.

For example, a petri dish containing 20 μL of Dimethylformamide (DMF) can be placed within a chamber. The chamber is then heated to 40° C. for 10 minutes, creating a fully vaporized DMF atmosphere within the chamber. Then, the substrate with nanoparticle arrays can be put in the chamber and subjected to DMF vapor for a crystallization time of 15 minutes. During the SVAR process, the crystal shape can be improved by diminishing the recrystallization rate following an Ostwald ripening processes.

After the SVAR, the perovskite crystals can be doped with the metal ion in a cation exchange reaction during a thermal annealing process. The substrate with perovskite nanoparticle arrays can be further heated to a temperature, for example to 100° C. for 10 minutes for thermal annealing. The thermal annealing can facilitate the cation exchange process with increased amount of, for example Mn²′ dopants introduced into perovskite crystals.

In embodiments, the ink includes equimolar amounts of a first perovskite precursor and a second perovskite precursor. In embodiments, the ink includes a 20:1:9 ratio of the first perovskite precursor, the second perovskite precursor, and the third perovskite precursor. In embodiments, for example, embodiments for producing a layered halide perovskite with a dopant ion, first perovskite precursor, second perovskite precursor, and third perovskite precursors could be used. For example, a ratio of 20:1:9 first perovskite precursor: second perovskite precursor: third perovskite precursor. For example, a 20:1:9: ratio of PEAl, MnI₂, and PbI₂ can be used in an ink to generate PEA₂Pb_{0.9}Mn_{0.1}I₄ nanocrystals.

In embodiments, the ink can be prepared to a target concentration. As demonstrated in the examples, the concentration of the ink can be used to control the nanocrystal size.

Selection of a suitable combination of precursors can be tailored to the ultimately desired halide perovskite. For example, if it the method is for forming a lead halide layered perovskite, B can be lead, and A can be the desired cation for the perovskite, for example, phenethylammonium (PEA).

A can be either organic or inorganic in either the mixed-ion (Formula I) or layered (Formula II) structures. For example, A can be one or more of methylammonium, formamidinium, cesium, rubidium. butylammonium, phenethylammonium, 3-(aminomethyl)piperidinium, and 4-(aminomethyl)piperidinium. In the layered structure A′ is an organic cation. For example, the organic cation, can be one or more of butylammonium, phenethylammonium, 3-(aminomethyl)piperidinium, and 4-(aminomethyl)piperidinium.

B can be one or more metal cations. For example, B can be one or more cations of lead, tin, cadmium, copper, ytterbium, bismuth, manganese, europium, and germanium. For example, the metal ion can be Mn²⁺, Cd²⁺, Cu²⁺, Yb³⁺, Er³⁺, Sb³⁺, Bi³⁺. For example, and without limitation, the precursor BX can be a MnCl₂, MnBr₂, MnI₂, CdCl₂, CdBr₂, CdI₂, CuCl₂, CuBr₂, CuI₂, YbCl₃, YbBr₃, YbI₃, ErCl₃, ErBr₃, ErI₃, SbCl₃, SbBr₃, SbI₃, BiCl₃, BiBr₃, BiI₃. The metal ion can be any metal ion.

B′ can be one or more dopant metal cations. B′ can be the same metal cation as B where the valency is different or can be a cation of a different metal. For example, B′ can be one or more cations lead, tin, cadmium, copper, ytterbium, erbium, antimony, bismuth, europium, manganese, and germanium. For example, the metal ion can be Mn²⁺, Cd²⁺, Cu²⁺, Yb³⁺, Er³⁺, Sb³⁺, Bi³⁺. For example, and without limitation, the precursor BX can be a MnCl₂, MnBr₂, MnI₂, CdCl₂, CdBr₂, CdI₂, CuCl₂, CuBr₂, CuI₂, YbCl₃, YbBr₃, YbI₃, ErCl₃, ErBr₃, ErI₃, SbCl₃, SbBr₃, SbI₃, BiCl₃, BiBr₃, BiI₃.

The methods of the disclosure use a cation exchange process assisted by thermal annealing to dope the halide perovskite nanocrystals with the dopant metal ion, B′. The dopant metal ion B′ can occupy B sites and displace some of the original B atoms. For example, in a PEA₂PbBr₄ perovskite, Mn⁺² ions can be introduced where the Mn⁺² replaces some of the Pb atoms as shown schematically in FIG. 1. The doped perovskite has a general composition as PEA₂Pb_{1-y}Mn_{y}Br₄.

The dopant metal ion B′ inserted into a B site can change the bandgap of the perovskite leading to multiple wavelength photoluminescence. For example, as the concentration of Mn increases in a doped perovskite, the PL emission changes from blue to orange. Without intending to be bound by theory, it is believed that the bandgap and consequently the wavelength of the photoluminescence can be selected by the inclusion of metal ions of different sizes and at different concentrations.

In embodiments, X can be a halogen, including any one or more of F, Cl, Br, and I. The halogen in the precursors can be the same or different depending on the halide structure desired.

The solvent can be one or more of one or more of dimethyformamide (DMF), dimethyl sulfoxide (DMSO), y-butyrolactone (GBL), and sulfolane. A combination of solvents can be used, for example, sulfolane and DMSO. For example, the sulfolane and DMSO can be combined in a solvent ratio of about 7:3. The solvent or combination of solvents is selected such that the halide perovskite precursor can be dissolved in the solvent. In embodiments, the solvent or solvent combination is further selected to have a low vapor pressure. Without intending to be bound by theory, it is believed that using solvents with low vapor pressure can improve the crystal quality.

The solvent can have a vapor pressure at 25° C. of 400 Pa or less, 380 Pa or less, or 360 Pa or less. For example, the vapor pressure at 25° C. can be about 50 Pa to about 400 Pa, about 56 Pa to about 380 Pa, about 100 Pa to about 300 Pa, about 50 Pa to about 100 Pa, or about 60 Pa to about 200 Pa. Other suitable vapor pressures at 25° C. can be about 50, 52, 54, 56, 58, 60, 65, 70, 75, 80, 85, 90, 95, 100, 110, 120, 130, 140, 150, 160, 170, 180, 190, 200, 210, 220, 230, 240, 250, 260, 280, 300, 310, 320, 330, 340, 350, 360, 370, 380, 390, or 400.

The solvent can have a viscosity of about 0.9 cP to about 10.1 cP, about 0.9 cP to about 5 cP, about 1 cP to about 8 cP, about 4 cP to about 10 cP. Other suitable amounts include about 0.9, 1, 1.2, 1.4, 1.6, 1.8, 2, 2.2, 2.4, 2.6, 2.8, 3, 3.2, 3.4, 3.6, 3.8, 4, 4.2, 4.4, 4.6, 4.8, 5, 5.2, 5.4, 5.6, 5.8, 6, 6.2, 6.4, 6.6, 6.8, 7, 7.2, 7.4, 7.6, 7.8, 8, 8.2, 8.4, 8.6, 8.8, 9, 9.2, 9.4, 9.6, 9.8, 10, and 10.1 cP.

The ink can be printed on any suitable substrate. For example, the substrate can be glass, ITO-coated glass, silicon, silicon oxide thin films, quartz, silicon nitride, or carbon. The substrate can be surface treated in embodiments. For example, the substrate can be surface treated with hexamethyldisiliazne (HMDS), octadecyltrichlorsilane (OTS), Poly(N,N′-bis-4-butylphenyl-N,N′-bisphenyl)benzidine (Poly-TPD), or polyvinylcarbazole (PVK). In embodiments, the substrate can be treated with a fluoropolymer. For example, the substrate can be treated with a fluoropolymer by reactive ion etching from CHF₃. The fluoropolymer surface treatment can have one or more repeating units selected from CF, CF₂, and CF₃.

In of the methods herein, the method can further include coating the pen array with a second ink after contacting the substrate to deposit the first ink; contacting the substrate with coated pen array to thereby deposit the second ink and form a pattern of second ink printed indicia on the substrate. The second ink can be for forming a mixed-ion (formula I) or layered halide perovskite (formula I) with or without doping. If a mixed ion halide perovskite without doping is desired, the second ink comprises at least one first perovskite precursor having the formula AX¹ and at least one second perovskite precursor having the formula BX²₂ dissolved in a solvent, wherein A is a cation, B is a metal, and X¹ and X² are each a halogen. If a layered halide perovskite (i.e., formula II) is desired, the second ink can include at least one first, first perovskite precursor having the formula A′X¹ and, when n is greater than 1 in the layered halide perovskite structure of formula II, a second, first perovskite precursor structure having the formula AX¹. If doping of the second halide perovskites being patterned is desired, then the ink for either the mixed ion or layered structure can further include a third perovskite precursor having the formula B′X¹ or B′X², where B′ is a dopant metal cation. Any of the cations, metal cations, dopant metal cations described above with respect to the first ink can be used in the second ink. The second ink is different from the first ink by one or more of the concentration of the first perovskite precursor (or first, first and/or second first perovskite precursor), the concentration of the second perovskite precursor, the solvent, the presence of a dopant, the selection of the dopant metal cation B′, the selection of A, the selection of B, the selection of X¹, and the selection of X², the pattern of second printed indicia form nanoreactors on the substrate and second ink halide perovskite nanocrystals nucleate and grow within each nanoreactor upon evaporation of the solvent thereby resulting in a substrate having at least two different halide perovskite nanocrystal arrays, the at least two different halide perovskite nanocrystal arrays differ in one or more of crystal structure, size, and composition.

The first and second inks can be coated on subsets of the pen array, for example, to define a coated pen pattern with the different inks and thus different halide perovskite structures to be formed on the substrate.

For example, the method can include forming the coated pen array by coating at least a portion of the pen array with the first ink and coating at least a portion of the pen array with the second ink, contacting the substrate with the coated pen array deposits both the first and second inks solutions to form a pattern of first and second printed indicia, the first and second printed indicia form first and second nanoreactors, respectively, on the substrate and upon evaporation of the solvent from the first and second nanoreactors, first and second halide perovskite nanocrystals nucleate and grow within each of the first and second nanoreactors, respectively. The first and second inks can be any of the ink compositions described herein.

In any of the methods of the disclosure, the coated pen array can be formed by coating the pen array with the first ink in a first gradient of coating weight across the array in a first direction; and coating the pen array with a second ink in a second gradient of coating weight across the pen array in a second direction, opposite the first direction, such that the coated pen array has a gradient of composition of the first and second inks coated thereon. The first and second inks can be any of the ink compositions described herein.

In any of the methods herein, the ink, first and/or second, can be coated on the pen array by spray coating. For example, spray coating can be used to apply one or more inks with or without a gradient of coat weight.

Metal ion-doped perovskites according to the disclosure can be layered perovskites with a general formula PEA₂Pb(X₁₋ₓX′ₓ)₄, where X is Br, X′ is iodine and the metal ion is Mn⁺², x can be a number between 0 and 1. For example, y can be 0, 0.1, 0.2, 0.3, 0.4, 0.5, 0.6, 0.7, 0.8, 0.9, 1, or any values therebetween.

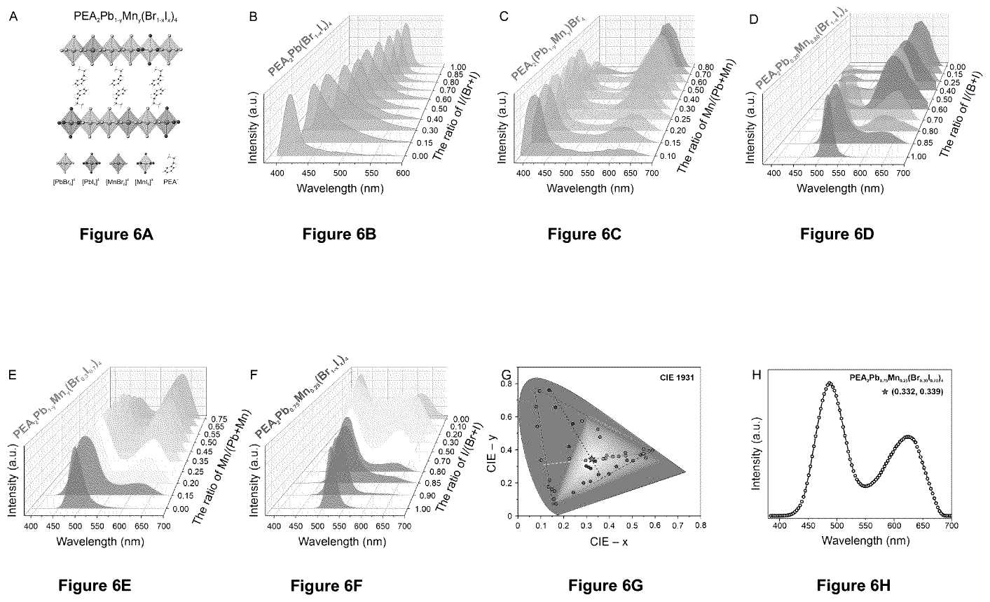

The metal ion-doped perovskites can have dual-wavelength photoluminescence emission as shown for example in FIGS. 6C and 6D. For example, a perovskite with a formula PEA₂Pb_{1-y}Mn_{y}(Br_{0.3}I_{0.7})₄ emits blue light (about 500 nm) when no Mn is included (y=0), as the concentration of Mn increases, the wavelength of the main PL peak increases towards orange (about 650 nm).

According to the disclosure, a metal ion doped perovskite can emit white light when the composition is PEA₂Pb_{0.75}Mn_{0.25}(Br_{0.3}I_{0.7})₄, as referenced in FIG. 6H.

### EXAMPLES

### Chemicals

Lead bromide (PbBr₂, 99.999%), lead chloride (PbCl₂, 99.999%), lead iodide (Pbl₂, 99.999%), manganese bromide (MnBr₂, 98%), manganese chloride (MnCl₂, 99.99%), manganese iodide (MnI₂, 99.99%), phenethylammonium bromide (PEABr, 98%), phenethylammonium iodide (PEAl, 98%), cesium bromide (CsBr, 99.999%), cesium chloride (CsCl, 99.999%), n-butylammonium bromide (BABr, 98%), dimethyl sulfoxide (DMSO, 99.9%), N,N-Dimethylformamide (DMF, 99.9%), sulfolane (99%) and hexamethyldisilazane (99%) were purchased from Sigma Aldrich. All chemicals were used as received without further purification. Silicon substrates were purchased from University Wafer and cut into 2 cm×2 cm pieces.

### Microscopy Characterization

Dark field (DF) images of NC megalibraries were taken using an optical microscope (Zeiss Axio Imager M2) with a halogen light source. Scanning electron microscopy was conducted using a JEOL JSM-7900FLV SEM at 5.0 kV-15.0 kV acceleration voltages. SEM-EDS maps were acquired with up to 20.0 kV accelerating voltage and large probe currents and analyzed with AZtec (Oxford Instruments). Atomic force microscopy was performed using a Bruker Dimension Icon AFM in tapping mode, and data analysis was performed using NanoScope Analysis software. Transmission electron microscopy (TEM) was performed on a JEOL ARM200CF equipped with a cFEG operated at 200 kV. Diffraction patterns were obtained using a Gatan OneView CMOS camera. Confocal photoluminescence (PL) images and PL spectra were taken using a Leica DiveB Sp8 multiphoton confocal laser scanning microscope. A Physics Mai Tai tunable laser (690-1040 nm) was used to tune the wavelength of excitation light. The lifetime decay data were collected and analyzed using the Leica X software.

### Single-Particle Optical Studies

Single-particle optical studies were performed in a closed-cycle helium cryostat (Montana Instruments). A 375-nm pulsed laser was directed using a beam splitter (Thorlabs BSW26R) through a mirror mounted on a scanning S-335 piezo platform (Physik Instrumente), a scan lens (Thorlabs LSM03-VIS), a 100-mm tube lens (Thorlabs TTL100-A), and a built-in objective (Zeiss Epiplan-Neofluar 100×/0.90 NA). The sample emission was directed through the same beam splitter into an imaging spectrometer (Andor, Shamrock SR-303i-B) or an air-cooled electron-multiplying charge-coupled device camera (EMCCD Andor Zyla 4.2P). A grating of 300 lines/mm dispersed the emitted light onto the cameras to record the spectra using an integration time of 3 s unless otherwise specified. All spectra underwent background correction. To identify single particles, the emission was sent to an avalanche photodiode (APDs) (Micro-Photon-Devices PDM) for fluorescence imaging. For each measurement series, the temperature, power, or repetition rate was adjusted while recording the emission from the same individual perovskite crystal. In the case of the temperature-dependent measurements, the sample crystal was identified and focused on between every measurement step to compensate for temperature-dependent sample drift.

### Synthesis of Mn²⁺-Doped Perovskite Nanocrystal (NC) Megalibraries.

Metal ion-doped perovskite megalibraries were synthesized based on the modified EC-PPL method (Science 2008, 321, 1658; Sci. Adv. 2020, 39, 4959.). Taking Mn²⁺ doped PEA₂PbBr₄ (PEA: Phenethylammonium) perovskites as an example, the preparation of the solution ink involved dissolving the mixture of 2 mmol PEABr, 0.75 mmol PbBr₂ and 0.25 mmol MnBr₂ precursors in the organic solvent (e.g., 10 mL dimethyl sulfoxide (DMSO)). After dissolving all the precursors fully, 0.1 mmol/mL Mn²⁺ doped PEA₂PbBr₄ perovskite ink was obtained with Mn doping concentration of 25%. For Mn²⁺-doped PEA₂PbI₄ perovskite NC megalibraries, 2 mmol PEAl, 0.75 mmol PbI₂, and 0.25 mmol MnI₂ were fully dissolved in 10 mL of DMSO to yield the precursor ink. For Mn²⁺-doped BA₂PbBr₄ perovskite NC megalibraries, 2 mmol BABr, 0.75 mmol PbBr₂, and 0.25 mmol MnBr₂ were fully dissolved in 10 mL of DMSO to yield the precursor ink. For Mn²⁺-doped CsPbCl₃ perovskite NC megalibraries, 1 mmol CsCl, 0.75 mmol PbCl₂, and 0.25 mmol MnCl₂ were fully dissolved in 10 mL of DMSO to yield the precursor ink. For Mn²⁺-doped CsPbBr₃ perovskite NP megalibraries, 1 mmol CsBr, 0.75 mmol PbBr₂, and 0.25 mmol MnBr₂ were fully dissolved in 10 mL of DMSO to yield the precursor ink. The Mn²⁺ doping concentration was adjusted by changing the precursor amounts.

Silicon wafers were selected as substrates for the megalibraries, they were surface treated to increase hydrophobicity using the following protocol: the silicon wafers were placed overnight into a chamber with vials containing a hexamethyldisilazane (HMDS)/hexane mixture (volume ratio=1:1) to yield HMDS molecules on their surface and then treated with CHF₃ in a reactive ion etching (RIE) process.

The polymer pen arrays were fabricated following a published protocol using h-polydimethylsiloxane (h-PDMS).²⁶ Briefly, a pen array was loaded into the piezo scanner of a desktop nanopatterning instrument (TERA-Fab M series, TERA-print, LLC) and further leveled parallel to the substrate. Then, the pen array was removed from the nanopatterning instrument, and treated with oxygen plasma for 1 min. For single-composition perovskite NC megalibraries, the pen array was spin-coated with the appropriate precursor ink at a spin speed of 3,000 rpm for 1 min. For PEA₂Pb_{1-y}Mn_{y}(Br₁₋ₓIₓ)₄ perovskite NC megalibraries, a spray-inking process was conducted for gradient composition tuning for the inked pen array. After the air plasma treatment at 30 W for 1 min, a pen array was secured under a spray gun (ViscoTec). A customized mask was placed on top of the pen array and only the central 1.5 cm×1.5 cm area was exposed for inking and patterning purposes. The nozzle from the spray gun was centered over one corner of the exposed area by moving the pen array location. The spray controller was programmed to deliver 4 μL of ink at a rate of 3 mL/min and a pressure of 0.5 bar. After spraying two diagonal corners, gradient composition tuning was achieved for the inked pen array along the diagonal. After spray inking, the inked pen array was placed in the air for 20 min before the patterning process to reduce the excess ink amount and improve the spray homogeneity.

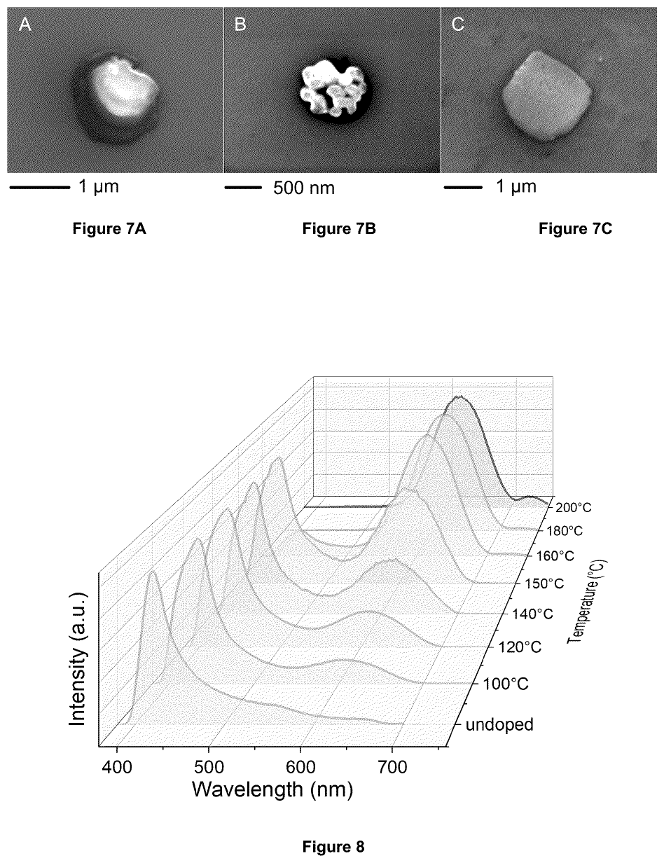

As is shown in FIG. 1, nanoreactors were formed by using pre-inked pen arrays, creating thousands of droplets consisting of metal precursors on a substrate upon contact. Due to spatial confinement and fast evaporation, the coalescence of different types of precursors and the formation of single particles can be achieved in these nanoreactors during crystal growth. Solvent vapor-assisted recrystallization (SVAR) and thermal annealing treatment were observed to enhance the crystal quality and PL properties (FIG. 7). Solvent vapor assisted recrystallization was performed by first placing a petri dish containing 20 μL of Dimethylformamide (DMF) within a chamber. The chamber was then heated to 40° C. for 10 minutes, creating a fully vaporized DMF atmosphere within the chamber. Then, the substrate with nanoparticle arrays was placed in the chamber and exposed to DMF vapor for an additional 15 minutes. The SVAR step was found to improve the perovskite crystal shapes by diminishing the recrystallization rate following an Ostwald ripening process. For the thermal annealing step, the substrates with perovskite nanoparticle arrays were further heated to 150° C. for annealing for 10 minutes. Thermal annealing can facilitate the cation exchange process with higher doping efficiency, resulting in stronger dopant PL emissions of the obtained perovskite NPs as shown in FIG. 8.

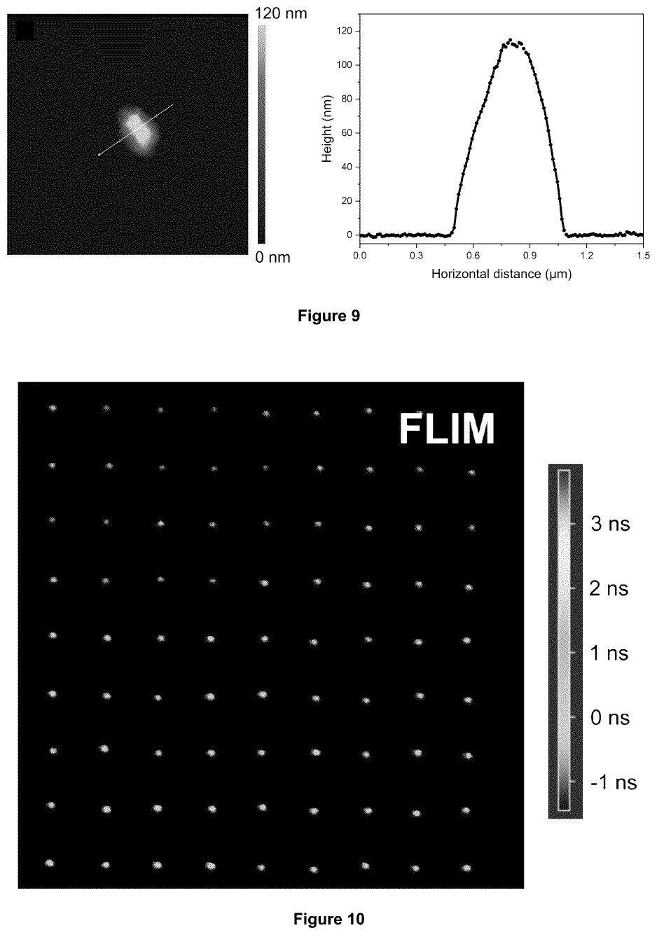

Highly ordered and periodic Mn²⁺ doped PEA₂PbBr₄ perovskite NP arrays were synthesized showing uniform and well-defined shapes in FIG. 2A. The morphology of as-synthesized NPs was characterized by scanning electron microscopy (SEM) (FIG. 2B) and atomic force microscopy (AFM) (FIG. 2D). Energy-dispersive x-ray spectroscopy (EDS) elemental mapping revealed that Mn element was uniformly distributed in the PEA₂PbBr₄ perovskite NPs, supporting the successful doping process (FIG. 2C). Atomic force microscopy (AFM) height images revealed that the Mn²⁺-doped two-dimensional (2D) PEA₂PbBr₄ perovskite NCs have a thickness of approximately 115 nm with a typical width-to-height ratio of ˜5:1 (FIGS. 2D and 9). Transmission electron microscopy (TEM) analysis of a Mn²⁺-doped PEA₂PbBr₄ NC confirmed its structural morphology and selected-area electron diffraction (SAED) indicated that the synthesized NCs were single-crystalline in nature (FIG. 2E).

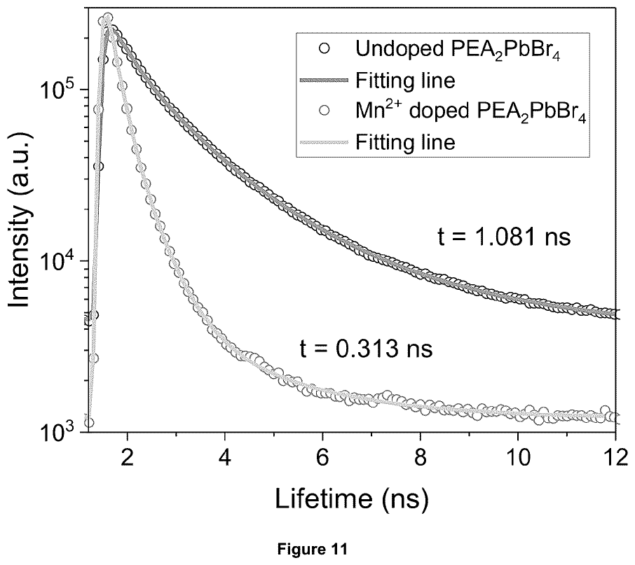

The PL properties and lifetime decays were studied using a multiphoton confocal laser scanning microscope (MP CLSM) together with a fluorescence lifetime imaging microscope (FLIM). In FIGS. 2F-2G and 10, Mn²⁺ doped PEA₂PbBr₄ perovskite NP arrays exhibited strong PL emissions in both blue and orange channels (Blue channel: from 380 nm to 500 nm, orange channel: from 500 nm to 700 nm), indicating dual-wavelength PL characteristics. This was further confirmed by the representative PL spectra obtained from individual NPs within the doped perovskite NP arrays (FIG. 2H). The average lifetime for the blue PL emissions was around 0.313 ns, which was shorter than that of undoped PEA₂PbBr₄ perovskite NPs around 1.081 ns. This finding was in good agreement with previous reports, indicating an accelerated exciton recombination rate after the doping process (FIG. 11).

Single-Particle Optical Studies of Mn²⁺-Doped PEA₂PbBr₄ Perovskite NC Megalibraries

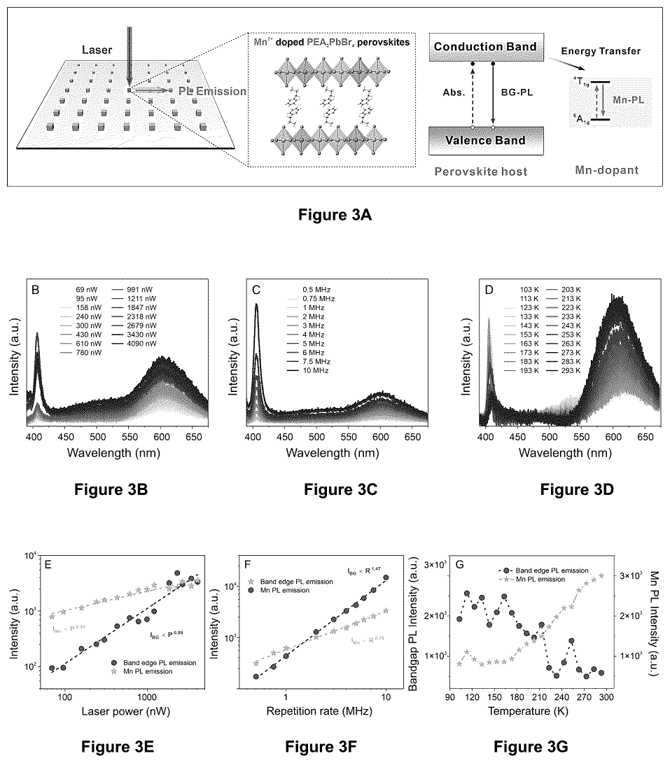

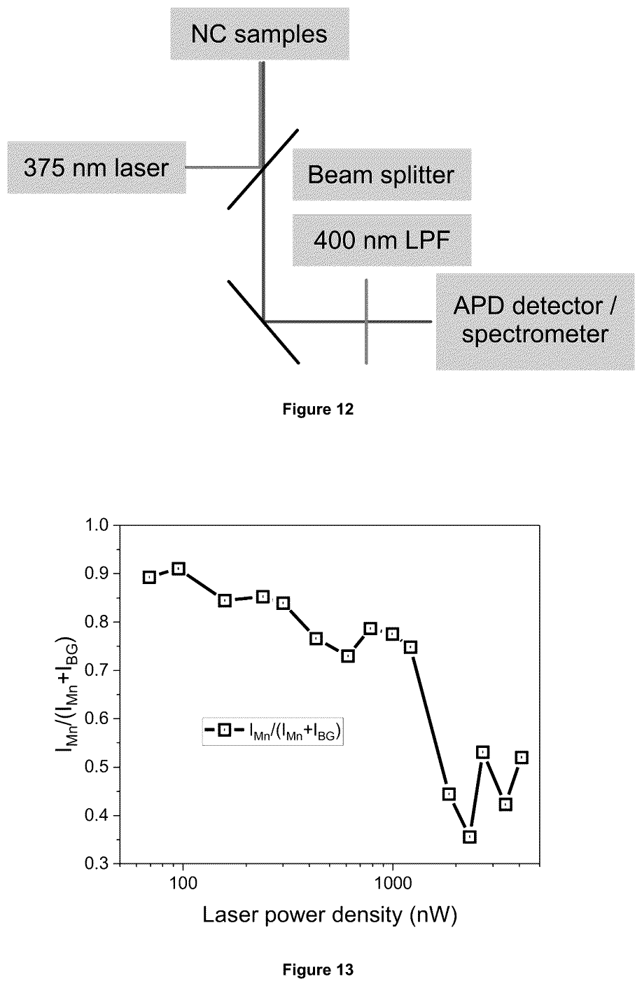

Single-particle optical studies were investigated to gain a deeper understanding of the photophysical mechanisms behind the dual-wavelength PL emissions from Mn²⁺ doped PEA₂PbBr₄ perovskite NP arrays. As shown in FIGS. 3A and 12, PL emission signals were detected when the laser was illuminated on the individual perovskite NPs. FIGS. 3B and 3E show the power-dependent PL spectra of Mn²⁺ doped PEA₂PbBr₄ perovskite NPs. It can be observed that the intensity of both bandgap edge PL and Mn PL increased as the laser power density increased from 100 nW to 10 μW and that the perovskite PL became slightly saturated when the laser power reached 2679 nW. The relationship of PL intensity and laser excitation power followed the equation: I∝P^{k}.

The relationship of peak intensity (I) and laser power (P) followed the equation: I∝P^{k}, where k was fitted as 0.99 (k_{BG}) and 0.34 (k_{Mn}), respectively (FIG. 3E). The percentage of photons emitted based on Mn PL as a share of the total emitted photons is defined as I_{Mn}/(I_{BG}+I_{Mn}). As laser power increased, I_{Mn}/(I_{BG}+I_{Mn}) decreased from 0.9 to 0.4, a reflection of decreased photon emission based on Mn PL as the power increased (FIG. 13). With the increased laser excitation power, the enhancement of band edge PL emission was stronger than that of Mn PL, indicating the involvement of two different types of photophysical processes: exciton recombination in the case of perovskite PL and energy transfer processes in the case of Mn PL. Since the exciton recombination rate is faster than the energy transfer rate, perovskite PL is enhanced compared to Mn PL as the laser power increased. The perovskite PL saturation at high laser excitation indicated that there was a threshold beyond which higher power can induce non-radiative processes.

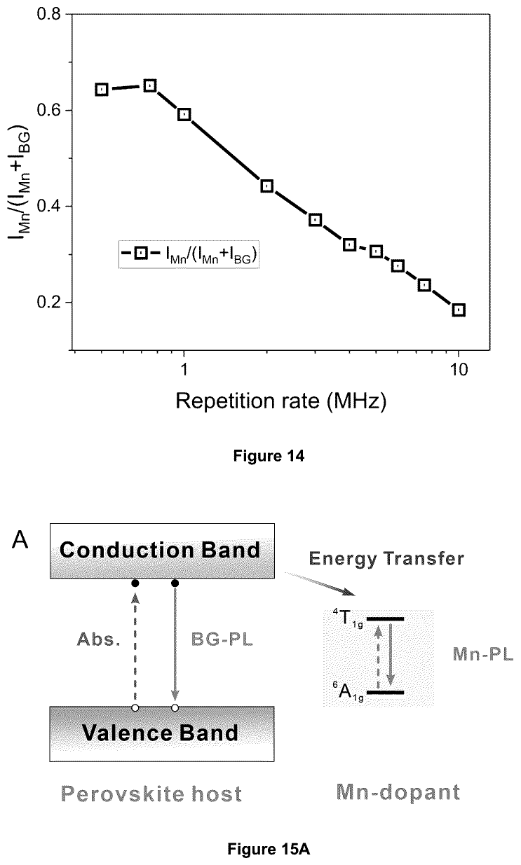

Similarly, when PL was investigated as a function of laser repetition rate (R) while keeping the total power constant (i.e., the frequency at which laser pulses are delivered to the sample), the relationship between these two variables went as: I∝Rⁿ (FIGS. 3C, 3F, and 14). As laser repetition rate increased, both perovskite and Mn PL intensities increased owing to the increased exciton recombination and more efficient energy transfer. However, the energy transfer process was found to be slower than exciton recombination process. In addition, because the locations of the main PL peaks did not change, the thermal effects from the higher repetition rate were likely minor. Consequently, n_{Mn} was smaller than n_{BG} and I_{Mn}/(I_{BG}+I_{Mn}) decreased with increasing laser repetition rate (FIGS. 3F and 14).

Temperature-dependent PL spectra were also explored for perovskite NP arrays over a temperature range of 103K to 293K, as shown in FIGS. 3D and 3G. As the temperature decreased, the perovskite PL intensity increased, while the Mn PL intensity decreased. The ratio of Mn PL emission to band edge PL emission decreased at lower temperatures, exhibiting a color transition from orange to blue. Based on these findings, the mechanisms for the dual-wavelength PL emissions were proposed in FIG. 3A. Under light excitation, electrons were excited from the valance band (ground states) into the conduction band (excited states), forming excitons through the recombination of the excited electrons and holes, resulting in the band edge PL in the blue range. The color of band edge PL was determined by the bandgap of perovskite hosts, which was influenced by their halide compositions and crystal structures. This further demonstrated the property differences observed when two different photophysical pathways are operational. Without intending to be bound by any theory, it is believed that at lower temperatures, the probability of the radiative decay of excitons is higher, permitting enhanced perovskite PL. It is also believed that the increased intensity of the Mn PL at temperatures higher than 173 K, implies a thermally activated energy transfer process from host excitons to Mn²⁺ dopants. Additionally, mediating trap states are also believed to exist in the NCs, requiring high enough energy to overcome the energy barrier to energy transfer based on the Arrhenius equation.

Without intending to be bound by any theory, it is believed that the origins for the observed dual-wavelength emission can be illustrated by FIG. 3A and described as follows: under laser excitation electrons are excited from the valence band (ground states) into the conduction band (excited states) in the host perovskite NCs, excitons are formed via photon absorption and can recombine, resulting in blue perovskite PL; further upon Mn²⁺ doping, energy transfer can also occur between the perovskite hosts and the dopants, leading to dual-wavelength PL emission. It is also believed that the exciton recombination and energy transfer processes are enhanced with increasing laser power excitation and repetition rate, both, and that the effects increase faster in perovskite PL than in Mn PL. At lower temperatures, PL is enhanced in the undoped perovskite due to increased radiative exciton recombination and reduced in Mn doped materials due to the host-to-dopant energy transfer following a thermally activated process.

### A General Strategy for Synthesizing Libraries of Mn²⁺-Doped Perovskite NC Megalibraries.

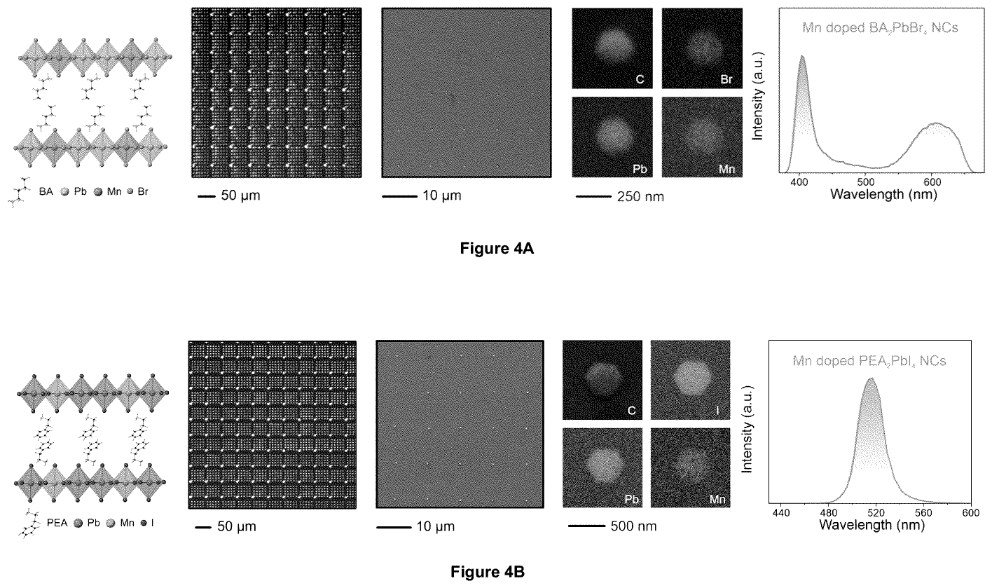

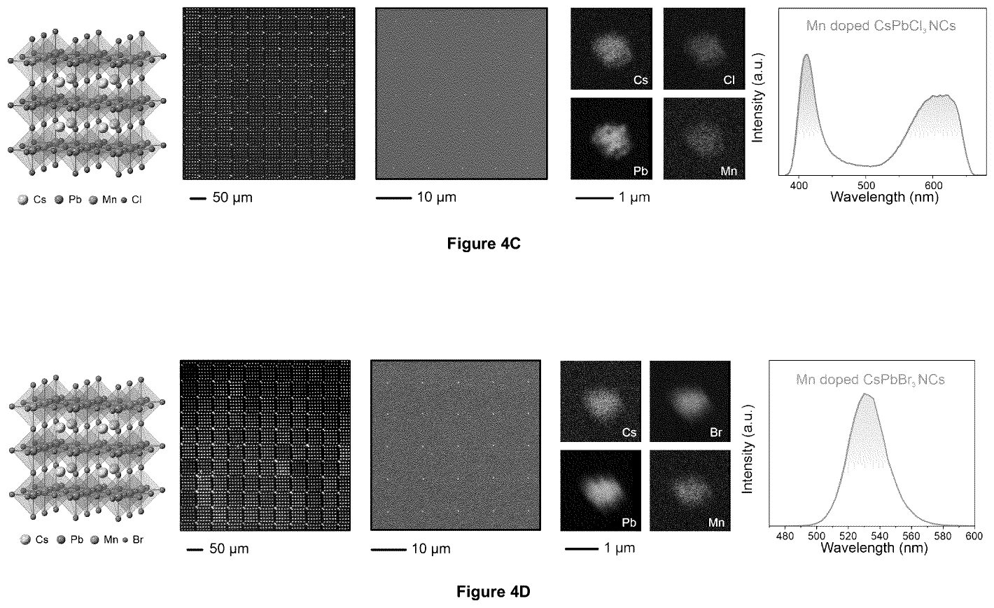

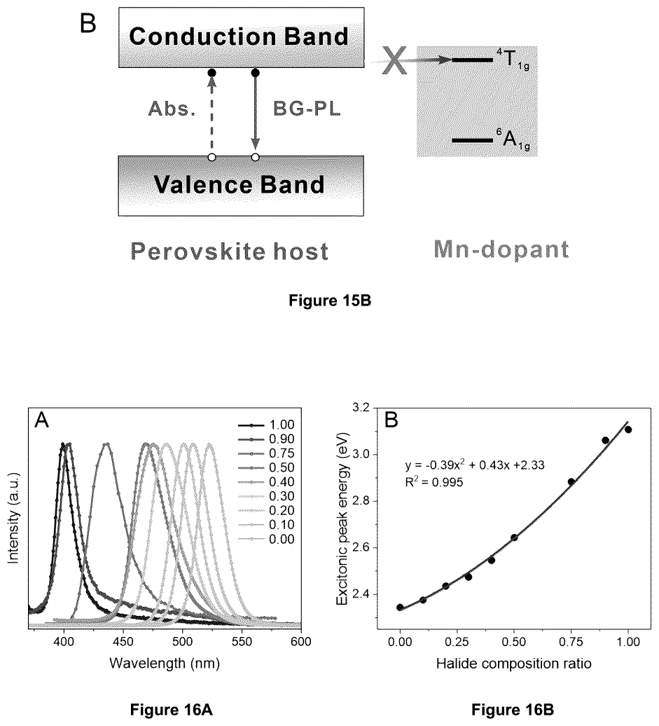

Methods according to the disclosure were used to investigate the effects of Mn²⁺ doping on a broader range of perovskites. NC Megalibraries of four different perovskite host materials with varied compositions, crystal phases, and bandgaps were selected, specifically BA₂PbBr₄ (BA: butylammonium), CsPbCl₃, PEA₂PbI₄, and CsPbBr₃. Using different chemical precursors, including AX, PbX₂ and MnX₂ with A: BA, PEA, Cs; X: Cl, Br, I. Despite the different halide composition, PEA₂PbBr₄ and PEA₂PbI₄ perovskites exhibited similar crystal phases (triclinic phases) and dimensionalities (2D structures) (FIGS. 4A-4B). BA₂PbBr₄ perovskites also possessed 2D layered structures in an orthorhombic cell. All-inorganic CsPbCl₃ and CsPbBr₃ perovskites exhibited connected networks of corner-to-corner sharing 3D octahedra, and they were stable in the cubic or orthorhombic phase (FIGS. 4C-4D). The patterned Mn²⁺-doped perovskite NCs had uniform particle sizes and high crystallinity regardless of the composition, crystal phase, and dimensionality of the perovskite hosts. EDS mapping also indicated that Mn was uniformly distributed throughout the individual NCs in all megalibraries, validating this method as a viable route to accessing a variety of Mn²⁺-doped NCs with different types of host materials. BA₂PbBr₄ and CsPbCl₃ perovskites possessed a wide bandgap (approximately 3 eV), which was large enough to observe host-to-dopant energy transfer and thus generate dual-wavelength emission after Mn²⁺ doping (FIGS. 4A and 4C). In contrast, the bandgaps of PEA₂PbI₄ and CsPbBr₃ perovskites were smaller (approximately 2.4 eV), and intrinsic exciton recombination was favored over energy transfer (FIG. 15). Therefore, Mn²⁺-doped PEA₂PbI₄ and CsPbBr₃ NCs only exhibited single-wavelength emission (green) with a peak centered at 517 nm (PEA₂PbI₄) and 530 nm (CsPbBr₃) without additional Mn PL peak. Without intending to be boudn by theory, it is believed that these methods can be used to advantageously tune the compositions of all A/B/X sites in perovskite crystal structures and their corresponding photophysical properties (i.e., PL emissions or bandgaps).

### High-Throughput Combinatorial Synthesis and Screening of Perovskite NC Megalibraries.

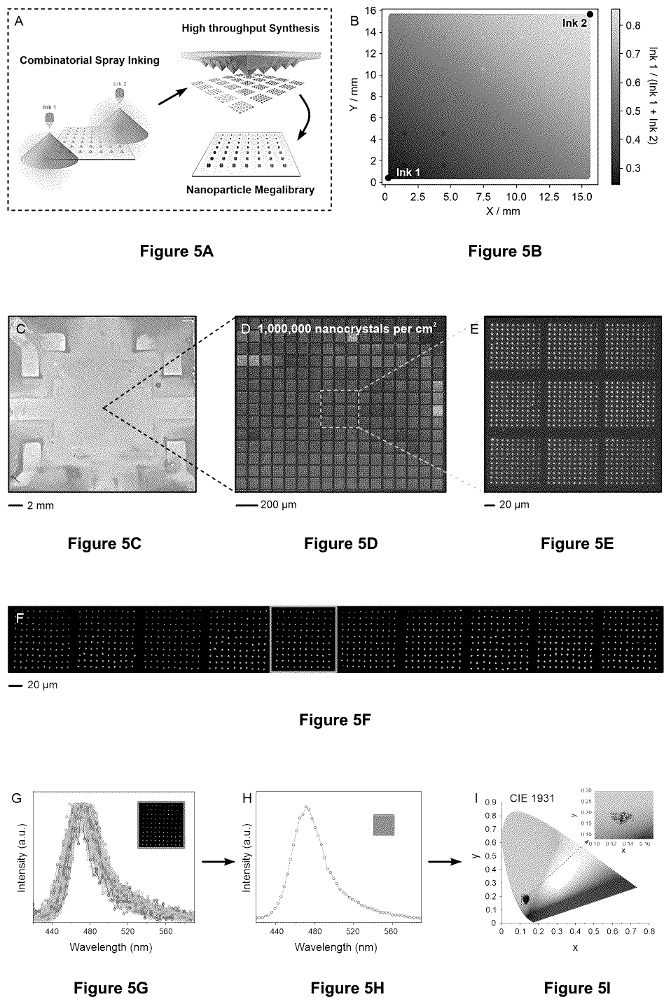

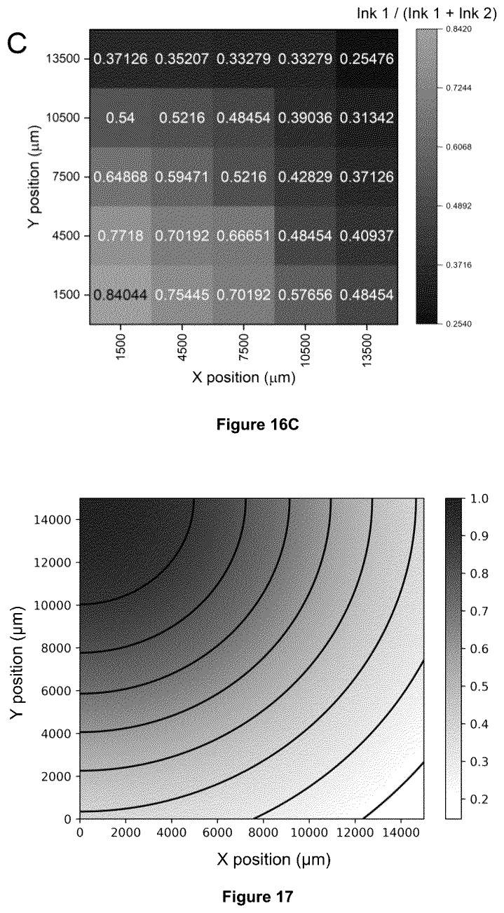

Combinatorial spray-inking was demonstrated for deliberately controlling the compositions and volumes of inks on each tip in the pen arrays (FIG. 5A). In contrast to spin coating, which was used to generate uniform ink distributions on all tips, the spray-inking process provided a gradient distribution of each precursor ink and allowed for the mixing of multiple types of precursor inks onto tips in such a way that information about ink composition and pen location could be established (FIGS. 5A-5B). For example, by spraying two different precursor inks on two opposite corners of the diagonal of a pen array, a gradient of inks can be sprayed from corner to corner. To simulate and evaluate this process quantitatively, two representative reference inks (i.e., MAPbCl₃ and MAPbBr₃ precursor inks) were sprayed on the corners of a glass or Si substrate that was pre-treated with O₂ plasma. After solvent evaporation under ambient conditions, a perovskite film containing various mixed halide compositions was obtained on the substrate and characterized using optical PL signals. Due to the quadratic relationship between PL peak energy and halide composition for MAPbCl₃₋ₓBrₓ (0≤x≤1) mixed halide perovskites (FIG. 16), the composition ratio distributions at precise locations (composition ratio=Ink 1/[Ink 1+Ink 2]), given the spraying profile, could be quantitatively plotted, and these data were linked to the PL peak energy gathered from the sprayed perovskite film on the substrate. With further 2D Gaussian distribution fitting (FIG. 5B), the entire two-ink spray profile as a function of composition distribution was simulated, facilitating the composition determination for the perovskite NC megalibraries. Positions that were ink 1-rich and ink 2-rich were located at the corners, matching well with the spray centers. Hence, gradient halide composition tuning was achieved on the diagonal of the sprayed substrates or pen arrays. A singular Gaussian fit for a one-ink spray profile was also plotted, displaying the radial composition distribution with a R² score of 0.983, close to that in previous reports using other materials (FIG. 17). After combinatorial inking, uniform and large-scale Mn²⁺-doped perovskite NC megalibraries were synthesized (FIGS. 5C-5E), yielding approximately 2 million Mn²⁺-doped perovskite NCs with different halide compositions, Mn-doping concentrations, and coded locations on a 2.25 cm² Si substrate.

Scanning confocal PL microscopy was used to study the PL emission of the perovskite NC megalibraries. For example, the compositions and locations of the individual NCs in PEA₂Pb(Br₁₋ₓIₓ)₄ (0≤x≤1) perovskite NC megalibraries were correlated and could be extracted from the spray profile (FIG. 5B). The PL images of the NC megalibraries and the corresponding PL spectra for each individual NC in the arrays were further examined. For example, 10 PEA₂PbBr₄₋₄ₓI₄ₓ NC arrays with varied halide compositions were selected and their PL images were analyzed (FIGS. 5B and 5F). As x (meaning I concentration) increased, the NC PL peak position shifted to longer wavelengths due to the decreased bandgap, and a color transition from purple to blue to green was observed (FIG. 5F). In addition, the PL spectra for 100 individual NCs in the selected PEA₂PbBr₂I₂ array displayed similar PL profiles (FIG. 5G), which indicated that uniform NCs could be prepared. These 100 PL spectra were averaged (FIG. 5H) and also plotted in the Commission Internationale de I'Elcairage (CIE) chromaticity diagram with specific chromaticity coordinates (FIG. 5I). The chromaticity coordinates for this NC array exhibited a small distribution, and the coordinates for the average PL spectra were further utilized to represent the whole selected NC array in the megalibraries (FIGS. 5F-5I). Through this process, the relationships between the compositions and their PL spectra together with chromaticity coordinates were established, forming the basis of using perovskite megalibraries for white-light emitter discovery.

### Accelerated Material Discovery for Single-Composition White-Light Emitters.

High-throughput synthesis and screening of PEA₂Pb_{1-y}Mn_{y}(Br₁₋ₓIₓ)₄ (0≤x≤1, 0≤y≤1) perovskite NC megalibraries can expedite on-demand inverse material design and discovery of single-composition white light emitters (FIG. 6A). The use of megalibraries to tune the composition of host perovskites and dopants (X site and B site) to provide structures with rich PL emissions over a wide color gamut was explored (FIGS. 6B-6F). PEA₂Pb(Br₁₋ₓIₓ)₄ (0≤x≤1) perovskite megalibraries were synthesized by spraying PEA₂PbBr₄ and PEA₂PbI₄ precursor inks on pen arrays. The PL peaks of the resulting perovskites shifted to longer wavelengths (from 418 nm to 517 nm) when the ratio of [I/(Br+1)] increased, and a transition from blue to green emission was observed as the bandgaps of the host perovskites decreased (FIGS. 5F and 6B, and Table 1).

TABLE 1
Chromaticity coordinates for PEA₂Pb(Br₁₋ₓIₓ)₄
(0 ≤ x ≤ 1) perovskite megalibraries.

| | x | y |
|---|---|---|
| 0.00 | 0.165 | 0.073 |
| 0.15 | 0.156 | 0.102 |
| 0.30 | 0.159 | 0.150 |
| 0.40 | 0.147 | 0.161 |
| 0.50 | 0.133 | 0.176 |
| 0.60 | 0.137 | 0.217 |
| 0.70 | 0.100 | 0.337 |
| 0.80 | 0.085 | 0.541 |
| 0.85 | 0.078 | 0.661 |
| 1.00 | 0.094 | 0.756 |

Similarly, PEA₂Pb_{1-y}Mn_{y}Br₄ (0≤y≤1) perovskite megalibraries were synthesized by spraying PEA₂PbBr₄ and PEA₂MnBrₐ precursor inks with varied Mn²⁺ doping concentrations (Mn/(Mn+Pb)) on the pen arrays. An increase in the peak intensity ratio of Mn PL to perovskite PL and a shift of the PL emission from blue to orange were observed with increasing Mn⁺² concentration (FIG. 60 and Table 2). Without intending to be bound by theory, it is believed that the energy transfer efficiency between the host perovskites and dopants is enhanced as dopant concentration increases.

TABLE 2
Chromaticity coordinates for PEA₂Pb_{1-y}Mn_{y}Br₄
(0 ≤ y ≤ 1) perovskite megalibraries.

| | x | y |
|---|---|---|
| 0.00 | 0.165 | 0.073 |
| 0.10 | 0.242 | 0.142 |
| 0.15 | 0.286 | 0.199 |
| 0.20 | 0.316 | 0.208 |
| 0.25 | 0.351 | 0.250 |
| 0.30 | 0.397 | 0.254 |
| 0.40 | 0.431 | 0.297 |
| 0.50 | 0.476 | 0.336 |
| 0.60 | 0.502 | 0.334 |
| 0.70 | 0.535 | 0.371 |
| 0.80 | 0.590 | 0.400 |

Perovskite NC megalibraries of PEA₂Pb_{0.20}Mn_{0.30}(Br₁₋ₓIₓ)₄ (0≤x≤1) were obtained by spray-inking the tips with PEA₂Pb_{0.20}Mn_{0.80}Br₄ and PEA₂Pb_{0.2}Mn_{0.8}I₄ precursor solutions (FIG. 6D and Table 3). As x increased, the PL of PEA₂Pb_{0.20}Mn_{0.30}(Br₁₋ₓIₓ)₄ (0≤x≤1) perovskites became more dominated by perovskite emission, and an orange-to-green PL color transition was observed. The peak positions of the perovskite host PL shifted to longer wavelengths, and the intensity ratio of Mn PL to perovskite PL decreased as well, indicative of smaller bandgaps for the host materials with decreased energy transfer efficiency.

TABLE 3
Chromaticity coordinates for PEA₂Pb_{0.20}Mn_{0.80}(Br₁₋ₓIₓ)₄
(0 ≤ x ≤ 1) perovskite megalibraries.

| | x | y |
|---|---|---|
| 1.00 | 0.095 | 0.755 |
| 0.85 | 0.280 | 0.572 |
| 0.80 | 0.350 | 0.524 |
| 0.70 | 0.358 | 0.477 |
| 0.60 | 0.549 | 0.403 |
| 0.50 | 0.469 | 0.382 |
| 0.40 | 0.573 | 0.391 |
| 0.25 | 0.559 | 0.352 |
| 0.15 | 0.548 | 0.376 |
| 0.00 | 0.590 | 0.400 |

A composition tuning triangle in a CIE chromaticity diagram was constructed by integrating these three different perovskite NC megalibraries (FIG. 6G). The left border, corresponding to the green-to-blue region, was occupied by PEA₂Pb(Br₁₋ₓIₓ)₄ (0≤x≤1) megalibraries. The bottom border displaying the blue-to-orange transition was populated by the PEA₂Pb_{1-y}Mn_{y}Br₄ (0≤y≤1) perovskite megalibraries. The right border corresponding to the orange-to-green emission was occupied by the PEA₂Pb_{0.20}Mn_{0.80}(Br₁₋ₓIₓ)₄ (0≤x≤1) perovskite megalibraries. This diagram successfully demonstrated the high tunability of PL emissions for PEA₂Pb_{1-y}Mn_{y}(Br₁₋ₓIₓ)₄ (0≤x≤1, 0≤y≤1) perovskite NC megalibraries, and the methods of the disclosure provided insight into composition-PL-chromaticity coordinate relationships, allowing for the precise control over the optical properties of doped perovskites.

Enabled by the high-throughput screening, on-demand inverse material design was conducted to discover single-composition white light emitters based on the composition tuning triangle and composition-function relationships. PEA₂Pb_{0.75}Mn_{0.25}(Br₁₋ₓIₓ)₄ and PEA₂Pb_{1-y}Mn_{y}(Br_{0.300}I_{0.70})₄ perovskite megalibraries were prepared (FIGS. 6E-6F and Tables 4-5) and PEA₂Pb_{0.75}Mn_{0.25}(Br_{0.30}I_{0.70})₄ perovskites were identified as ideal single-composition white light emitter with a CIE chromaticity coordinate of (0.332, 0.339), which is very close to that of the standard neutral white light (0.33, 0.33) (FIG. 6H). Demonstrating that these perovskite NC megalibraries are a model system to accelerate the exploration of new light emitters with on-demand customized color design, and high potential as phosphors for applications such as light-emitting diodes.

TABLE 4
Chromaticity coordinates for PEA₂Pb_{1-y}Mn_{y}(Br_{0.30}I_{0.70})₄
(0 ≤ y ≤ 1) perovskite megalibraries.

| | x | y |
|---|---|---|
| 0.00 | 0.100 | 0.337 |
| 0.15 | 0.224 | 0.346 |
| 0.20 | 0.296 | 0.336 |
| 0.25 | 0.332 | 0.339 |
| 0.35 | 0.372 | 0.345 |
| 0.45 | 0.382 | 0.348 |
| 0.50 | 0.388 | 0.365 |
| 0.55 | 0.415 | 0.359 |
| 0.65 | 0.440 | 0.361 |
| 0.75 | 0.471 | 0.364 |

TABLE 5
Chromaticity coordinates for PEA₂Pb_{0.75}Mn_{0.25}(Br₁₋ₓIₓ)₄
(0 ≤ x ≤ 1) perovskite megalibraries.

| | x | y |
|---|---|---|
| 1.00 | 0.136 | 0.760 |
| 0.90 | 0.164 | 0.655 |
| 0.85 | 0.240 | 0.557 |
| 0.80 | 0.223 | 0.420 |
| 0.70 | 0.332 | 0.339 |
| 0.50 | 0.297 | 0.302 |
| 0.30 | 0.338 | 0.331 |
| 0.20 | 0.318 | 0.288 |
| 0.10 | 0.309 | 0.294 |
| 0.00 | 0.352 | 0.250 |

The foregoing description is given for clearness of understanding only, and no unnecessary limitations should be understood therefrom, as modifications within the scope of the disclosure may be apparent to those having ordinary skill in the art.

All patents, patent applications, government publications, government regulations, and literature references cited in this specification are hereby incorporated herein by reference in their entirety. In the case of conflict, the present description, including definitions, will control.

Throughout the specification, where the compounds, compositions, methods, and/or processes are described as including components, steps, or materials, it is contemplated that the compounds, compositions, methods, and/or processes can also comprise, consist essentially of, or consist of any combination of the recited components or materials, unless described otherwise. Component concentrations can be expressed in terms of weight concentrations, unless specifically indicated otherwise. Combinations of components are contemplated to include homogeneous and/or heterogeneous mixtures, as would be understood by a person of ordinary skill in the art in view of the foregoing disclosure.

### REFERENCES

1. J. Chen, H. Xiang, J. Wang, R. Wang, Y. Li, Q. Shan, X. Xu, Y. Dong, C. Wei, H. Zeng, Perovskite White Light Emitting Diodes: Progress, Challenges, and Opportunities. ACS Nano 15, 17150-17174 (2021).
2. W. Y. Hong, B. N. N. N. Rahmat, Energy consumption, CO₂ emissions and electricity costs of lighting for commercial buildings in Southeast Asia. Sci. Rep. 12, 13805 (2022).
3. M.-H. Fang, W.-T. Huang, R.-S. Liu, Evolutionary Generation of Phosphor Materials and Their Progress in Future Applications for Light-Emitting Diodes. Chem. Rev. 122, 11474-11513 (2022).
4. S. Nakamura, T. Mukai, M. Senho, Candela-Class High-Brightness InGaN/AlGaN Double-Heterostructure Blue-Light-Emitting Diodes. Appl. Phys. Lett. 64, 1687-1689 (1994).
5. X. Chen, H. Xiang, R. Wang, Y. Wang, Y. Wang, H. Zeng, Perovskite-Organic Coupling WLED: Progress and Perspective. Adv. Funct. Mater. 33, 2304750. (2023).
6. J. Chen, J. Wang, X. Xu, J. Li, J. Song, S. Lan, S. Liu, B. Cai, B. Han, J. T. Precht, D. Ginger, H. Zeng, Efficient and Bright White Light-Emitting Diodes Based on Single-Layer Heterophase Halide Perovskites. Nat. Photonics 15, 238-244 (2020).
7. M. D. Smith, H. I. Karunadasa, White-Light Emission from Layered Halide Perovskites. Acc. Chem. Res. 51, 619-627 (2018).
8. M. C. Gather, A. Kohnen, K. Meerholz White Organic Light-Emitting Diodes. Adv. Mater. 23, 233-248 (2010).
9. S. Pathak, N. Sakai, F. W. R. Rivarola, S. D. Stranks, J. Liu, G. E. Eperon, C. Ducati, K. Wojciechowski, J. T. Griffiths, A. A. Haghighirad, A. Pellaroque, R. H. Friend, H. J. Snaith. Perovskite Crystals for Tunable White Light Emission. Chem. Mater. 27, 8066-8075 (2015).
10. H. Wu, S. Xu, H. Shao, L. Li, Y. Cui, C. Wang, Single Component Mn-Doped Perovskite-Related CsPb₂ClₓBr₅₋ₓ Nanoplatelets with A Record White Light Quantum Yield of 49%: A New Single Layer Color Conversion Material for Light-Emitting Diodes. Nanoscale 9, 16858-16863 (2017).
11. T. Bai, X. Wang, Z. Wang, S. Ji, X. Meng, Q. Wang, R. Zhang, P. Han, K. Han, J. Chen, F. Liu, B. Yang, Highly Luminescent One-Dimensional Organic-Inorganic Hybrid Double-Perovskite-Inspired Materials for Single-Component Warm White Light-Emitting Diodes. Angew. Chem. Int. Ed. Engl. 62, 202213240 (2023).
12. R. Sun, P. Lu, D. Zhou, W. Xu, N. Ding, H. Shao, Y. Zhang, D. Li, N. Wang, X. Zhuang, B. Dong, X. Bai, H. Song, Samarium-Doped Metal Halide Perovskite Nanocrystals for Single-Component Electroluminescent White Light-Emitting Diodes. ACS Energy Lett. 5, 2131-2139 (2020).
13. L. Protesescu, S. Yakunin, M. I. Bodnarchuk, F. Krieg, R. Caputo, C. H. Hendon, R. X. Yang, A. Walsh, M. V. Kovalenko, Nanocrystals of Cesium Lead Halide Perovskites (CsPbX₃, X═Cl, Br, and I): Novel Optoelectronic Materials Showing Bright Emission with Wide Color Gamut. Nano Lett. 15, 3692-3696 (2015).
14. Q. A. Akkerman, G. Raino, M. V. Kovalenko, L. Manna, Genesis, Challenges and Opportunities for Colloidal Lead Halide Perovskite Nanocrystals. Nat. Mater. 17, 394-405 (2018).
15. J. Huang, M. Lai, J. Lin, P. Yang, Rich Chemistry in Inorganic Halide Perovskite Nanostructures. Adv. Mater. 30, 1802856 (2018).
16. A. K. Guria, S. K. Dutta, S. D. Adihikari, N. Pradhan, Doping Mn²⁺ in Lead Halide Perovskite Nanocrystals: Successes and Challenges. ACS Energy Lett. 2, 1014-1021 (2017).
17. W. Liu, Q. Lin, H. Li, K. Wu, I. Robel, J. M. Pietryga, V. I. Klimov, Mn²⁺-Doped Lead Halide Perovskite Nanocrystals with Dual-Color Emission Controlled by Halide Content. J. Am. Chem. Soc. 138, 14954-14961 (2016).
18. H. Shao, X. Bai, H. Cui, G. Pan, P. Jing, S. Qu, J. Zhu, Y. Zhai, B. Dong, H. Song, White Light Emission in Bi³⁺/Mn²⁺ Ion Co-Doped CsPbCl₃ Perovskite Nanocrystals. Nanoscale 10, 1023-1029 (2018).
19. R. D. Piner, J. Zhu, F. Xu, S. Hong, C. A. Mirkin, “Dip-Pen” Nanolithography. Science 283, 661-663 (1999).
20. G. Liu, S. H. Petrosko, Z. Zheng, C. A. Mirkin, A. Evolution of Dip-Pen Nanolithography (DPN): From Molecular Patterning to Materials Discovery. Chem. Rev. 120, 6009-6047 (2020).
21. F. Huo, Z. Zheng, G. Zheng, L. R. Giam, H. Zhang, C. A. Mirkin, Polymer Pen Lithography. Science 321, 1658-1660 (2008).
22. D. J. Eichelsdoerfer, X. Liao, M. D. Cabezas, W. Morris, B. Radha, K. A. Brown, L. R. Giam, A. B. Braunschweig, C. A. Mirkin, Large-area molecular patterning with polymer pen lithography. Nat. Protocols 8, 2548-2560 (2013).
23. J. H. Swisher, L. Jibril, S. H. Petrosko, C. A. Mirkin, Nanoreactors for particle synthesis. Nat. Rev. Mater. 7, 428-448 (2022).
24. M. Lai, D. Shin, L. Jibril, C. A. Mirkin, Combinatorial Synthesis and Screening of Mixed Halide Perovskite Megalibraries. J. Am. Chem. Soc. 144, 13823-13830 (2022).
25. P. T. Smith, Z. Ye, J. Pietryga, J. Huang, C. B. Wahl, J. K. H. Orbeck, C. A. Mirkin, Molecular Thin Films Enable the Synthesis and Screening of Nanoparticle Megalibraries Containing Millions of Catalysts. J. Am. Chem. Soc. 145, 14031-14043 (2023).
26. P. T. Smith, C. B. Wahl, J. K. H. Orbeck, C. A. Mirkin, Megalibraries: Supercharged Acceleration of Materials Discovery. MRS Bull. 48, 1172-1183 (2023).
27. E. J. Kluender, J. L. Hedrick, K. A. Brown, C. A. Mirkin, Catalyst discovery through megalibraries of nanomaterials. Proc. Natl. Acad. Sci. 116, 40-45 (2019).
28. J. S. Du, D. Shin, T. K. Staney, C. Musumeci, Z. Xie, Z. Huang, M. Lai, L. Sun, W. Zhou, N. P. Stern, V. P. Dravid, C. A. Mirkin, Halide Perovskite Nanocrystal Arrays: Multiplexed Synthesis and Size-Dependent Emission. Sci. Adv. 6, 4959 (2020).
29. D. Shin, M. Lai, Y. Shin, J. S. Du, L. Jibril, J. M. Rondinelli, C. A. Mirkin, From Heterostructures to Solid-Solutions: Structural Tunability in Mixed Halide Perovskites. Adv. Mater. 35, e2205923 (2023).
30. J. Li, Z. Li, T. Cai, D. Shin, C. Chen, C. A. Mirkin, Non-Centrosymmetric Single Crystalline Biomolecular Nano-Arrays for Responsive Electronics. Adv. Mater. 36, 2408153 (2024).
31. C.-H. Lu, G. V. Biesold-McGee, Y. Liu, Z. Kang, Z. Lin, Doping and Ion Substitution in Colloidal Metal Halide Perovskite Nanocrystals. Chem. Soc. Rev. 49, 4953-5007 (2020).
32. D. Liang, Y. Peng, Y. Fu, M. J. Shearer, J. Zhang, J. Zhai, Y. Zhang, R. J. Hamers, T. L. Andrew, S. Jin, Color-Pure Violet-Light-Emitting Diodes Based on Layered Lead Halide Perovskite Nanoplates. ACS Nano 10, 6897-6904 (2016).
33. J. Liu, C. Gao, X. He, Q. Ye, L. Ouyang, D. Zhuang, C. Liao, J. Mei, W. Lau, Improved Crystallization of Perovskite Films by Optimized Solvent Annealing for High Efficiency Solar Cell. ACS Appl. Mater. Interfaces 7, 24008-24015 (2015).
34. A. Biswas, R. Bakthavatsalam, J. Kundu, Efficient Exciton to Dopant Energy Transfer in Mn²⁺-Doped (C₄H₉NH₃)₂PbBr₄ Two-Dimensional (2D) Layered Perovskites. Chem. Mater. 29, 7816-7825 (2017).
35. S. K. Dutta, A. Dutta, S. D. Adhikari, N. Pradhan, Doping Mn²⁺ in Single-Crystalline Layered Perovskite Microcrystals. ACS Energy Lett. 4, 343-351 (2019).
36. S. Ji, X. Yuan, Z. Liu, L. Zhao, K. Zhao, J. Zheng, J. Zhao, J. Wang, Photo- and Thermal-Induced Ion Migration and Phase Separation in Mn-Doped Two-Dimensional PEA₂PbX₄ Perovskite. ACS Appl. Mater. Interfaces 15, 33087-33094 (2023).
37. Y. Zhong, D. Seeberger, E. M. Herzig, A. Kohler, F. Panzer, C. Li, S. Huettner, The Impact of Solvent Vapor on the Film Morphology and Crystallization Kinetics of Lead Halide Perovskites during Annealing. ACS Appl. Mater. Interfaces 13, 45365-45374 (2021).
38. W. Denk, J. H. Strickler, W. W. Webb, Two-Photon Laser Scanning Fluorescence Microscopy. Science 248, 73-76 (1990).
39. T. W. J. Gadella Jr., T. M. Jovin, R. M. Clegg, Fluorescence lifetime imaging microscopy (FLIM): Spatial resolution of microstructures on the nanosecond time scale. Biophys. Chem. 48, 221-239 (1993).
40. T. Cai, J. Wang, W. Li, K. Hills-Kimball, H. Yang, Y. Nagaoka, Y. Yuan, R. Zia, O. Chen, Mn²⁺/Yb³⁺ Codoped CsPbCl₃ Perovskite Nanocrystals with Triple-Wavelength Emission for Luminescent Solar Concentrators. Adv. Sci. 7, 2001317 (2020).
41. A. De, N. Mondal, A. Samanta, Luminescence Tuning and Exciton Dynamics of Mn-doped CsPbCl₃ Nanocrystals. Nanoscale 9, 16722-16727 (2017).
42. Q. Sun, S. Wang, C. Zhao, J. Leng, W. Tian, S. Jin, Excitation-Dependent Emission Color Tuning from an Individual Mn-Doped Perovskite Microcrystal. J. Am. Chem. Soc. 141, 20089-20096 (2019).
43. N. K. Kumawat, A. Dey, A. Kumar, S. P. Gopinathan, K. L. Narasimhan, D. Kabra, Band Gap Tuning of CH₃NH₃Pb(Br₁₋ₓClₓ)₃ Hybrid Perovskite for Blue Electroluminescence. ACS Appl. Mater. Interfaces 7, 13119-13124 (2015).
44. C. B. Wahl, M. Aykol, J. H. Swisher, J. H. Montoya, S. K. Suram, C. A. Mirkin, Machine learning-accelerated design and synthesis of polyelemental heterostructures. Sci. Adv. 7, 5505 (2021).

What is claimed is:

1. A method of forming a metal ion doped mixed-ion perovskite nanocrystal array having a plurality of metal ion doped halide perovskite nanocrystals arranged in a pattern, each halide perovskite being of the formula ABX₃, wherein A comprises one or more cations, B comprises one or more metal cations, X comprises one or more halogens, the method comprising:
contacting a substrate with a coated pen array coated with a first ink to thereby deposit the first ink as a pattern of printed indicia on the substrate, wherein the first ink comprises at least one first perovskite precursor having the formula AX¹, at least one second perovskite precursor having the formula BX²₂, and at least one third perovskite precursor having the formula B′X¹₂ and/or B′X²₂ dissolved in a solvent, wherein B′ comprises one or more dopant metal cation, and X¹ and X² are each a halogen, and the printed indicia form nanoreactors on the substrate and a halide perovskite nanocrystal nucleates and grows within each nanoreactor to form the halide perovskite nanocrystal array;
exposing the halide perovskite nanocrystals to a crystallization solvent vapor for recrystallization of the halide perovskite; and
thermally annealing the halide perovskite nanocrystals to promote a cation exchange process whereby B′ diffuses into the halide perovskite nanocrystals and exchanges with a portion of B to thereby form the doped perovskite nanocrystals,
wherein B′ and B are different metal cations or metal cations of the same metal having different valency, and
wherein X¹ and X² are the same halogen when X comprises one halogen and X¹ and X² are different halogens when X comprises more than one halogen.

2. The method of claim 1, wherein A is selected from the group consisting of methylammonium, formamidinium, cesium, rubidium, butylammonium, phenethylammonium, 3-(aminomethyl)piperidinium, and 4-(aminomethyl)piperidinium, and combinations thereof.

3. The method of claim 1, wherein exposing the halide perovskite nanocrystals to the crystallization solvent vapor comprises heating a crystallization solvent in a chamber to vaporize the crystallization solvent and placing the halide perovskite nanocrystals into the chamber for exposure to the crystallization solvent vapor at a crystallization temperature for a crystallization time.

4. The method of claim 1, wherein the crystallization solvent has a flash point less than about 60° C., optionally wherein the crystallization solvent is dimethylformamide (DMF).

5. The method of claim 1, wherein the crystallization temperature is about 35° C. to 55° C. and the crystallization time is at least 10 minutes, and/or wherein thermal annealing comprises heating to about 90° C. to about 110° C. for about 10 minutes to about 20 minutes.

6. The method of claim 1, wherein thermal annealing comprises heating to about 90° C. to about 110° C. for about 10 minutes to about 20 minutes.

7. The method of claim 1, wherein a molar ratio of the at least one first perovskite precursor to the at least one second perovskite precursor in the first ink is about 1:1.

8. The method of claim 1, wherein B and B′ each comprises one or more cations of one or more metals independently selected from the group consisting of lead, tin, cadmium, copper, ytterbium, erbium, antimony, bismuth, europium, manganese, and germanium.

9. The method of claim 1, wherein X¹ is one or more of I, Br, Cl, F, and At and/or X² is one or more of I, Br, Cl, F, and At.

10. The method of claim 1, comprising coating the pen array with a second ink after contacting the substrate to deposit the first ink;
contacting the substrate with the coated pen array to thereby deposit the second ink and form a pattern of second ink printed indicia on the substrate, wherein:
the second ink comprises at least one first perovskite precursor having the formula AX¹, at least one second perovskite precursor having the formula BX²2, and optionally at least one third perovskite precursor having the formula B′X¹₂ and/or B′X²₂ dissolved in a solvent, wherein A is a cation, A′ is an organic cation, B is a metal, B′ is a dopant metal, and X¹ and X² are each a halogen and can be the same or different halogens,
the second ink is different from the first ink by one or more of the concentration of the first perovskite precursor, the concentration of the second perovskite precursor, the solvent, the selection of A, the selection of B, the selection of B′, the selection of X¹, and the selection of X²,
the pattern of second printed indicia form nanoreactors on the substrate and the second ink halide perovskite nanocrystals nucleate and grow within each nanoreactor upon evaporation of the solvent thereby resulting in a substrate having at least two different halide perovskite nanocrystal arrays,
the at least two different halide perovskite nanocrystal arrays differ in one or more of crystal structure, size, and composition.

11. The method of claim 1, wherein the coated pen array is formed by coating the pen array comprising coating a subset of pens of the pen array to define a coated pen pattern, the coated pen pattern defining the pattern of the printed indicia.

12. The method of claim 1, wherein the coated pen array is formed by coating at least a portion of the pen array with the first ink and coating at least a portion of the pen array with a second ink, the second ink comprising at least one first perovskite precursor having the formula AX¹, at least one second perovskite precursor having the formula BX²₂, and optionally at least one third perovskite precursor having the formula B′X¹₂ and/or B′X²₂ dissolved in a solvent, wherein A is a cation, B is a metal, B′ is a dopant metal, and X¹ and X² are each a halogen and can be the same or different halogens, wherein:
the second ink is different from the first ink by one or more of the concentration of the first perovskite precursor, the concentration of the second perovskite precursor, the solvent, the selection of A, the selection of B, the selection of B′, the selection of X¹, and the selection of X²,
a subset of pens of the polymer pen array are coated with the first ink and a different subset of pens of the polymer pen array are coated with the second ink,
contacting the substrate with the coated pen array deposits both the first and second inks solutions to form a pattern of first and second printed indicia,
the first and second printed indicia form first and second nanoreactors, respectively, on the substrate and upon evaporation of the solvent from the first and second nanoreactors, first and second halide perovskite nanocrystals nucleate and grow within each of the first and second nanoreactors, respectively.

13. The method of claim 1, wherein the coated pen array is formed by coating the pen array with the first ink in a first gradient of coating weight across the array in a first direction; and
coating the pen array with a second ink in a second gradient of coating weight across the pen array in a second direction, opposite the first direction, such that the coated pen array has a gradient of composition of the first and second inks coated thereon, wherein:
the second ink comprises at least one first perovskite precursor having the formula AX¹, and at least one second perovskite precursor having the formula BX²₂, and optionally at least one third perovskite precursor having the formula B′X¹₂ or B′X²₂ dissolved in a solvent, wherein A is a cation, B is a metal, B′ is a dopant metal, and X¹ and X² are each a halogen and can be the same or different halogens, and
the second ink is different from the first ink by one or more of the concentration of the first perovskite precursor, the concentration of the second perovskite precursor, the solvent, the selection of A, the selection of B, the selection of B′, the selection of X¹, and the selection of X².

14. A metal ion doped perovskite with tunable photoluminescence having a formula PEA₂Pb₁₋ₐB′ₐX_{y}X′_{4-y}, wherein X and X′ are each a halogen, B′ is the metal ion, and the metal ion is one or more of Mn²⁺, Cd²⁺, Cu²⁺, Yb³⁺, Er³⁺, Sb³⁺, Bi³⁺.

15. The metal ion doped perovskite of claim 14, wherein X is one of chlorine, bromine, iodine, and X′ is one of chlorine, bromine, iodine.

16. A metal ion doped perovskite having a formula PEA₂Pb_{0.75}Mn_{0.25}(Br_{0.3}I_{0.7})₄, wherein the metal ion doped perovskite emits white light with a CIE chromaticity coordinate of about (0.33, 0.33).

17. A method of forming a metal ion doped layered perovskite nanocrystal array having a plurality of metal ion doped halide perovskite nanocrystals arranged in a pattern, each halide perovskite being of the formula A′₂Aₙ₋₁BₙX₂ₙ₊₁, wherein n is at least 1, A′ comprises one or more organic compounds, A, when present, comprises one or more cations, and X comprises one or more halogens, the method comprising:
contacting a substrate with a coated pen array coated with a first ink to thereby deposit the first ink as a pattern of printed indicia on the substrate, wherein the first ink comprises at least one first perovskite precursor having the formula A′X¹, at least one second first perovskite precursor having the formula AX¹ when n is greater than 1, at least one second perovskite precursor having the formula BX²₂, and at least one third perovskite precursor having the formula B′X¹₂ and/or B′X²₂ dissolved in a solvent, and the printed indicia form nanoreactors on the substrate and a halide perovskite nanocrystal nucleates and grows within each nanoreactor to form the halide perovskite nanocrystal array;
exposing the halide perovskite nanocrystals to a crystallization solvent vapor for recrystallization of the halide perovskite; and
thermally annealing the halide perovskite nanocrystals to promote a cation exchange process whereby B′ diffuses into the halide perovskite nanocrystals and exchanges with a portion of B to thereby form the doped perovskite nanocrystals,
wherein B′ and B are different metal cations or metal cations of the same metal having different valency, and
wherein X¹ and X² are the same halogen when X comprises one halogen and X¹ and X² are different halogens when X comprises more than one halogen.

18. The method of claim 17, wherein A is selected from the group consisting of methylammonium, formamidinium, cesium, rubidium and A′ is selected from the group consisting of butylammonium, phenethylammonium, 3-(aminomethyl)piperidinium, and 4-(aminomethyl)piperidinium.

19. The method of claim 17, wherein B and B′ each comprise one or more cations of one or more metals independently selected from the group consisting of lead, tin, cadmium, copper, ytterbium, erbium, antimony, bismuth, europium, manganese, and germanium.

20. The method of claim 17, wherein X¹ is one or more of I, Br, Cl, F, and At and/or X² is one or more of I, Br, Cl, F, and At.
